(19) United States
(12) Patent Application Publication
(10) Pub. No.: US 2025/0234723 A1
(43) Pub. Date: Jul. 17, 2025

(54) Display Apparatus and Display Panel

(71) Applicant: LG Display Co., Ltd., Seoul (KR)

(72) Inventors: Jeong Ho Kim, Paju-si (KR); Dae Sung Jung, Paju-si (KR); Dae Kyu Kim, Paju-si (KR)

(21) Appl. No.: 18/745,413

(22) Filed: Jun. 17, 2024

(30) Foreign Application Priority Data
Jan. 16, 2024 (KR) 10-2024-0006762

(51) Int. Cl. H10K 59/126; H10K 59/121; H10K 59/131

(52) U.S. Cl. CPC H10K 59/126; H10K 59/1213; H10K 59/131

(57) ABSTRACT

A display apparatus may comprise a substrate, a base circuit layer on the substrate, the base circuit layer including a gate driving circuit, a pixel layer on the base circuit layer, the pixel layer including a plurality of subpixels, a first shielding layer between the base circuit layer and the pixel layer, and a second shielding layer between the substrate and the base circuit layer.

### CROSS-REFERENCE TO RELATED APPLICATION

This application claims priority to Republic of Korea Patent Application No. 10-2024-0006762 filed on Jan. 16, 2024, which is hereby incorporated by reference in its entirety.

### BACKGROUND

### Field

The present disclosure relates to a display apparatus and a display panel, and more specifically, to a display apparatus and a display panel with a narrow bezel structure.

### Description of Related Art

A vehicle means a transportation device that can move people or loads using kinetic energy. Here, the vehicle can include various types of transportation device that can transport people, such as a car, a truck, a bus, an airplane, and a ship.

### SUMMARY

For the safety and convenience of vehicle users, the vehicle may include various sensors and electronic devices, and functions of the vehicle are becoming more diverse.

Functions of the vehicle may include convenience functions to promote convenience of drivers and safety functions to promote safety of drivers or pedestrians.

Convenience functions may include technologies such as functions for providing infotainment (information and entertainment), an autonomous driving function, and a function for helping the driver secure visibility at night or in blind areas. For example, functions of active cruise control (ACC), smart parking assist system (SPAS), night vision (NV), head up display (HUD), and around view monitor (AVM), and adaptive headlight system (AHS) may be referred as convenience functions.

Safety functions may include technologies that ensure the safety of drivers or pedestrians, such as lane departure warning system (LDWS), lane keeping assist system (LKAS), and autonomous emergency braking (AEB) system, etc.

Meanwhile, a vehicle may include a display system with various types of display panels. A vehicle control device may provide various convenience functions and safety functions to the driver or passengers by controlling the information supplied to the internal display panel.

Since a gate driving circuit is connected to or placed in the non-display area (also called bezel) of the display panel in the display apparatuses, it is not easy to reduce the size of the non-display area (bezel) of the display panel.

Accordingly, a display apparatus and a display panel with a narrow bezel structure has been invented.

Aspects of the present disclosure may provide a display apparatus and a display panel with a narrow bezel structure.

Aspects of the present disclosure may provide a display apparatus comprising a substrate, a base circuit layer on the substrate, the base circuit layer including a gate driving circuit, a pixel layer on the base circuit layer, the pixel layer including a plurality of subpixels, a first shielding layer between the base circuit layer and the pixel layer, and a second shielding layer between the substrate and the base circuit layer.

Aspects of the present disclosure may provide a display panel comprising a substrate, a base circuit layer on the substrate, the base circuit layer including a gate driving circuit, a pixel layer on the base circuit layer, the pixel layer including a plurality of subpixels, a first shielding layer between the base circuit layer and the pixel layer, and a second shielding layer between the substrate and the base circuit layer.

Aspects of the present disclosure may provide a display apparatus comprising a substrate, a base circuit layer on the substrate, the base circuit layer including a gate driving circuit, a pixel layer on the base circuit layer, the pixel layer including a plurality of subpixels, and a shielding layer between the base circuit layer and the pixel layer.

According to aspects of the present disclosure, it has an effect capable of reducing a parasitic capacitance between a subpixel and a driving circuit while a gate driving circuit is disposed across a display area.

According to aspects of the present disclosure, it has an effect capable of reducing a parasitic capacitance between a base circuit layer including a gate driving circuit and a pixel layer including subpixels.

According to aspects of the present disclosure, it has an effect capable of reducing a parasitic capacitance between a base circuit layer including a gate driving circuit and an upper signal line.

According to aspects of the present disclosure, it has an effect capable of reducing a parasitic capacitance between nodes or signal lines within the gate driving circuit by a shielding structure disposed below the base circuit layer including the gate driving circuit.

According to aspects of the present disclosure, it is possible to reduce a size of a non-display area (bezel) of the display panel and to make a display apparatus lighter.

### BRIEF DESCRIPTION OF DRAWINGS

The accompanying drawings, which are included to provide a further understanding of the disclosure, and incorporated in and constitute a part of the disclosure, illustrate aspects of the disclosure and together with the description serve to explain principles of the disclosure.

FIG. 1 illustrates an interior of a vehicle according to embodiments of the present disclosure.

FIG. 2 illustrates a display apparatus according to embodiments of the present disclosure.

FIG. 3 is a block diagram illustrating a configuration of a gate driving circuit in a display apparatus according to embodiments of the present disclosure.

FIG. 4 illustrates a subpixel circuit according to embodiments of the present disclosure.

FIG. 5 illustrates a structure for driving a plurality of display panels according to embodiments of the present disclosure.

FIG. 6 is a cross-sectional diagram of a unit subpixel according to embodiments of the present disclosure.

FIG. 7 illustrates a light emitting element according to embodiments of the present disclosure.

FIG. 8 illustrates another example of a light emitting element in a display apparatus according to embodiments of the present disclosure.

FIG. 9 illustrates a circuit diagram of a unit subpixel according to embodiments of the present disclosure.

FIG. 10 illustrates a display panel with a structure of gate in array according to embodiments of the present disclosure.

FIG. 11 illustrates a structure of a base circuit layer in embodiments of the present disclosure.

FIG. 12 is a plan view illustrating a base circuit layer and a pixel layer according to embodiments of the present disclosure.

FIG. 13 is a perspective view illustrating a shielding structure according to embodiments of the present disclosure.

FIG. 14 is a cross-sectional view of a display area according to embodiments of the present disclosure.

FIG. 15 is a cross-sectional view illustrating a display area according to embodiments of the present disclosure.

FIG. 16 is a perspective view illustrating an example of a shielding layer according to embodiments of the present disclosure.

FIGS. 17 and 18 are cross-sectional views illustrating a display area according to embodiments of the present disclosure.

### DETAILED DESCRIPTION

Reference is now made in detail to aspects of the present disclosure, examples of which may be illustrated in the accompanying drawings. In the following description, when a detailed description of well-known methods, functions, the structures, or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

Where a term like “comprise,” “have,” “include,” “contain,” “constitute,” “make up of,” “formed of,” “composed of,” or the like is used with respect to one or more other elements (e.g., layers, films, regions, components, sections, members, parts, regions, areas, portions, steps, operations, and/or the like), one or more other elements may be added unless a term, such as “only” or the like is used. The terms used in the present disclosure are merely used in order to describe example aspects, and are not intended to limit the scope of the present disclosure. The terms of a singular form may include plural forms unless the context clearly indicates otherwise.

The word “exemplary” is used to mean serving as an example or illustration, unless otherwise specified. Embodiments are example embodiments. Aspects are example aspects. In one or more implementations, “embodiments,” “aspects,” “examples,” “embodiment,” and the like should not be construed to be preferred or advantageous over other implementations. An aspect, an example, an example aspect, or the like may refer to one or more aspects, one or more examples, one or more example aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts may be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the terms “first,” “second,” or the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A”, “B”, “(a)”, or “(b)”, or the like may be used. These terms are intended to identify the corresponding element(s) from the other element(s), and these are not used to define the essence, basis, order, sequence, or number of elements.

For the expression that an element (e.g., layer, film, region, component, section, or the like) is described as “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element, or that the entirety of the element is provided, disposed, connected, coupled, or the like in, on, with or to another element. The phrase that an element (e.g., layer, film, region, component, section, or the like) “contacts,” “overlaps,” or the like with another element may be understood, for example, as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms may mean a wider range of lines or directions within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item”, may represent (i) a combination of items provided by two or more of the first item, the second item, and the third item and (ii) only one of the first item, the second item, and the third item.

The expression of a first element, a second elements, “and/or” a third element should be understood to encompass one of the first, second, and third elements, as well as any and all combinations of the first, second and third elements. By way of example, A, B and/or C encompass only A; only B; only C; any of A, B, and C (e.g., A, B, or C); some combinations of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as different from one another. In another example, an expression “different from one another” may be understood as different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, and may be operated, linked, or driven together in various ways. Aspects of the present disclosure may be implemented or carried out independently from each other, or may be implemented or carried out together in a co-dependent or related relationship. In one or more aspects, the components of each apparatus according to various aspects of the present disclosure may be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning that is, for example, consistent with their meaning in the context of the relevant art and should not be interpreted in an idealized or overly formal sense, unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example aspects.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

“X-axis direction,” “Y-axis direction,” and “Z-axis direction,” should not be construed by a geometric relation only of a mutual vertical relation and may have broader directionality within the range that elements of the present disclosure may act functionally.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the present disclosure will be described in detail with reference to the accompanying drawings.

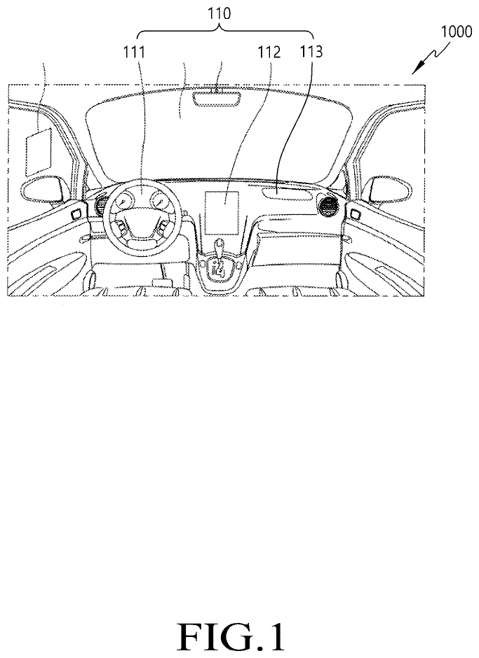

FIG. 1 illustrates an interior of a vehicle according to embodiments of the present disclosure.

Referring to FIG. 1, the interior of the vehicle 1000 according to aspects of the present disclosure may include a driver's seat, a passenger's seat, a dashboard, which has various instruments necessary for driving, disposed in front of the driver's seat and passenger's seat, and a center fascia with a control plate for electronic apparatuses.

The dashboard may include a first display panel 111 configured to display information necessary for driving, including a speedometer. The first display panel 111 may be referred to as a dashboard display panel.

The first display panel 111 is a display panel for allowing the vehicle 1000 to be driven safely by transmitting information for the driving status of the vehicle 1000 and the operation of various electronic apparatuses installed in the vehicle 1000 to the driver. The first display panel 111 disposed behind the steering wheel relative to the driver's seat may include a speedometer for indicating a driving speed, a tripmeter for indicating a driving distance, a tachometer for indicating engine rotation speed, a fuel gauge, a water temperature gauge, an engine temperature gauge, and various warning lamps.

The center fascia may be disposed between the driver's seat and the passenger's seat, and may correspond to the area where the dashboard and shift lever meet vertically. An audio, an air conditioner, a heater controller, a navigator, an air vent, a cigar jack, an ashtray, a cup holder, etc., may be disposed on the center fascia. Additionally, the center fascia may include a second display panel 112.

The second display panel 112 may display a route to the destination or display a map image corresponding to the current location, and may display a user interface related to the control of various electronic apparatuses in the vehicle 1000. Additionally, when the vehicle 1000 is connected to a mobile apparatus, a screen provided by the mobile apparatus may be displayed in the second display panel 112.

The second display panel 112 located between the driver's seat and the passenger's seat of the vehicle 1000 may be referred to as a center fascia display panel.

Additionally, a third display panel 113 may be further disposed on the front of the passenger's seat for the convenience of passengers. The third display panel 113 located on the passenger's seat may be referred to as the passenger display panel.

Moreover, the display panel 110 may include at least one of a front window display panel, a side mirror display panel, a rear mirror display panel and a side window display panel in addition to the dashboard display panel 111, a center fascia display panel 112, and the passenger display panel 113. Further, various types of display panels may be more installed.

The front window display panel may be a display panel that projects a virtual image on a partial area of the front window that may see through the front of the vehicle 1000. By displaying a vehicle speed, a remaining fuel, and route information through the front window display panel, it may minimize the driver's unnecessary shifting of gaze elsewhere.

The side mirror display panel may be a display panel that may display a side image captured through a side camera on a partial or entire area of a side mirror to view the side of the vehicle 1000. Therefore, the driver may check not only the side image reflected through the side mirror, but also the side image captured through the side camera through the side mirror display panel.

The rear mirror display panel may be a display panel that may display a rear image captured through a rear camera on a partial or entire area of a rear mirror to view the rear of the vehicle 1000. Therefore, the driver may check not only the rear image reflected through the rear mirror, but also the rear image captured through the rear camera through the rear mirror display panel.

The side window display panel may be a display panel for projecting a virtual image on a partial area of the side window that can see through the side of the vehicle 1000. A lot of information for the vehicle 1000 may be displayed through the side window display panel.

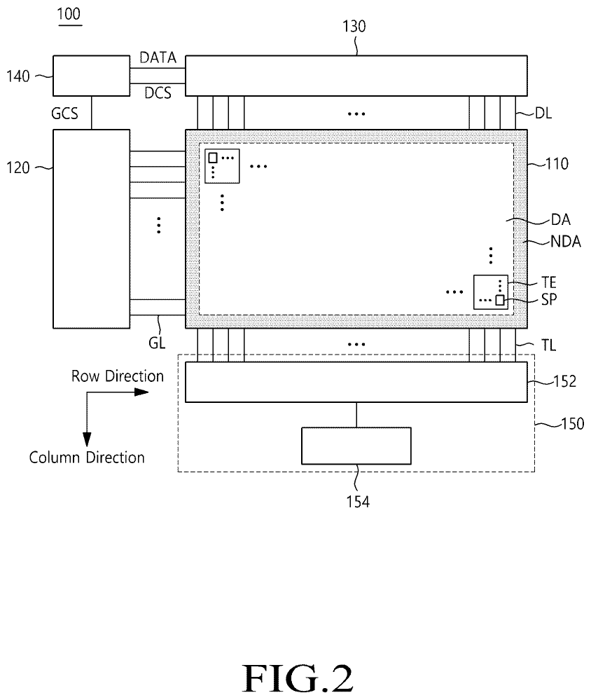

FIG. 2 illustrates a display apparatus according to embodiments of the present disclosure.

Referring to FIG. 2, a display apparatus 100 according to aspects of the present disclosure may include a display panel 110, a data driving circuit 130, a gate driving circuit 120, and a timing controller 140 as components configured to display images.

The display panel 110 may include a dashboard display panel 111, a center fascia display panel 112, and a passenger display panel 113, but aspects of the present disclosure are not limited thereto.

The display panel 110 may include a display area DA in which images are displayed and a non-display area NDA in which no image is displayed.

The non-display area NDA may be an outer area of the display area DA and be referred to as a bezel area. The non-display area NDA may be an area visible from the front of the display apparatus 100 or an area that is bent and not visible from the front of the display apparatus 100.

The display panel 110 may include a plurality of subpixels SP. For example, the display apparatus 100 may be various types of display apparatuses including a liquid crystal display apparatus, an organic light emitting display apparatus, a micro light emitting diode (micro-LED) display apparatus, and a quantum dot display apparatus, but aspects of the present disclosure are not limited thereto.

The structure of each of the plurality of subpixels SP may vary according to the type of the display apparatus 100. For example, when the display apparatus 100 is a self-emission display apparatus in which the subpixels SP emit light by themselves, each subpixel SP may include a light emitting element that emits light by itself, one or more transistors, and one or more capacitors.

The display panel 110 may further include various types of signal lines to drive the plurality of subpixels SP. For example, various types of signal lines may include a plurality of data lines DL transferring data signals (also referred to as data voltages or image data) and a plurality of gate lines GL transferring gate signals (also referred to as scan signals or emission signals).

The plurality of data lines DL and the plurality of gate lines GL may cross each other. Each of the plurality of data lines DL may be disposed to be extending in a column direction. Each of the plurality of gate lines GL may be disposed to be extending in a row direction.

Here, the column direction and the row direction are relative. For example, the column direction may be a vertical direction and the row direction may be a horizontal direction. As another example, the column direction may be a horizontal direction and the row direction may be a vertical direction.

The data driving circuit 130 may be a circuit configured to drive the plurality of data lines DL. The data driving circuit 130 may supply data signals to the plurality of data lines DL. The gate driving circuit 120 may be a circuit configured to drive the plurality of gate lines GL. The gate driving circuit 120 may supply gate signals to the plurality of gate lines GL.

The timing controller 140 may control the data driving circuit 130 and the gate driving circuit 120. The timing controller 140 may control driving timings for the plurality of data lines DL and driving timings for the plurality of gate lines GL.

The timing controller 140 may supply various types of data driving control signals DCS to the data driving circuit 130 to control the data driving circuit 130 and may supply various types of gate driving control signals GCS to the gate driving circuit 230 to control the gate driving circuit 120.

The data driving circuit 130 may supply data voltages to the plurality of data lines DL according to the driving timing control by the timing controller 140. The data driving circuit 130 may receive digital image data DATA from the timing controller 140 and may convert the received image data DATA into analog data voltages and output them to the plurality of data lines DL.

The gate driving circuit 120 may supply gate signals to the plurality of gate lines GL according to the timing control of the timing controller 140. The gate driving circuit 120 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL. The turn-on level voltage may be a high-level voltage, and the turn-off level voltage may be a low level voltage. For another example, the turn-on level voltage may be a low-level voltage, and the turn-off level voltage may be a high level voltage.

To provide a touch sensing function as well as an image display function, the display apparatus 100 may include a touch screen panel and a touch circuit 150 that senses the touch screen panel to detect whether a touch occurs by a touch object, such as a finger or pen, or the position of the touch.

The touch circuit 150 may include a touch driving circuit 152 that drives and senses the touch screen panel and generates and outputs touch sensing data and a touch controller 154 that may detect an occurrence of a touch or the position of the touch using touch sensing data.

The touch screen panel may include a plurality of touch electrodes TE as touch sensors. The touch screen panel may further include a plurality of touch lines TL for electrically connecting the plurality of touch electrodes TE and the touch driving circuit 152. The touch screen panel or touch electrode TE is also referred to as a touch sensor.

The touch screen panel may be disposed outside or inside the display panel 110. When the touch screen panel exists outside the display panel 110, the touch screen panel is referred to as an external-type touch screen panel. When the touch screen panel is of the external-type, the touch screen panel and the display panel 110 may be separately manufactured and may be combined. The external-type touch screen panel may include a substrate and a plurality of touch electrodes TE on the substrate.

When the touch screen panel provides inside the display panel 110, the touch screen panel is referred to as an internal-type touch screen panel. In the internal-type touch screen panel, the touch screen panel may be formed in the display panel 110 during a manufacturing process of the display panel 110.

The touch driving circuit 152 may supply a touch driving signal to at least one of the plurality of touch electrodes TE and detect a touch sensing signal transferred from at least one touch electrode TE among the plurality of touch electrodes TE, generating touch sensing data.

The touch circuit 150 may perform touch sensing in a self-capacitance sensing scheme or a mutual-capacitance sensing scheme.

When the touch circuit 150 performs touch sensing in the self-capacitance sensing scheme, the touch circuit 150 may perform touch sensing based on capacitance between each touch electrode TE and the touch object (e.g., finger or pen).

When the touch circuit 150 performs touch sensing in the mutual-capacitance sensing scheme, the touch circuit 150 may perform touch sensing based on capacitance between the touch electrodes TE.

According to the mutual-capacitance sensing scheme, the plurality of touch electrodes TE are divided into driving touch electrodes and sensing touch electrodes. The touch driving circuit 152 may drive the driving touch electrode by the touch driving signal and may detect the touch sensing signal from the sensing touch electrode.

According to the self-capacitance sensing scheme, each of the plurality of touch electrodes TE may serve both as a driving touch electrode and as a sensing touch electrode. The touch driving circuit 152 may drive all or some of the plurality of touch electrodes TE and sense all or some of the plurality of touch electrodes TE.

The touch driving circuit 152 and the touch controller 154 may be implemented as separate devices or as a single device.

In another example, the touch driving circuit 152 and the data driving circuit 130 may be implemented as separate integrated circuits. In another example, the whole or part of the touch driving circuit 152 and the whole or part of the data driving circuit 130 may be integrated into a single integrated circuit.

The display apparatus 100 according to embodiments of the present disclosure may be a self-emissive display apparatus having self-emissive light emitting elements disposed on the display panel 110, such as an organic light emitting display apparatus, a quantum dot display apparatus, a micro-LED display apparatus, but aspects of the present disclosure are not limited thereto.

The gate driving circuit 120 may include one or more gate driving integrated circuits (GDIC). The gate driving circuit 120 may be located at only one side (or one portion) or both sides (or both portions) of the display panel 110 depending on the driving method.

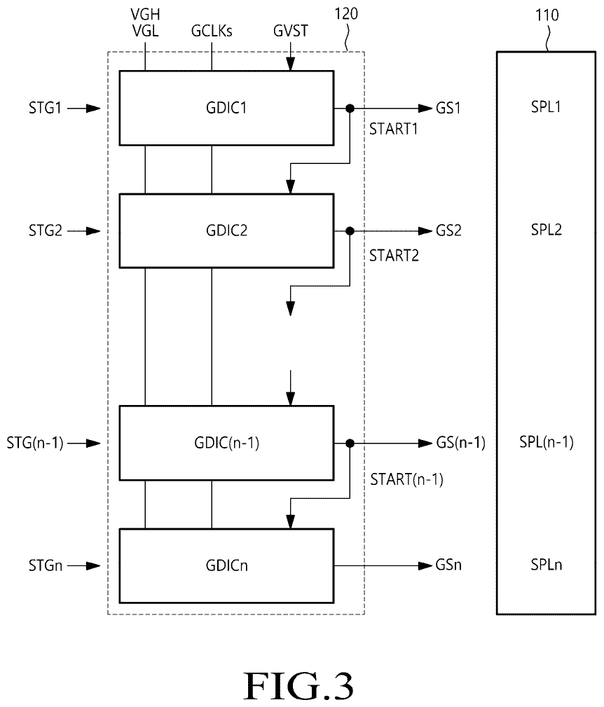

FIG. 3 is a block diagram illustrating a configuration of a gate driving circuit in a display apparatus according to embodiments of the present disclosure.

Referring to FIG. 3, the gate driving circuit 120 in the display apparatus 100 according to aspects of the present disclosure may be disposed in the non-display area or the display area of the display panel 110.

The gate driving circuit 120 may be composed of n stages STG1-STGn to which n (a natural number of 2 or more) gate driving integrated circuits GDIC1-GDICn are dependently connected. Each of the gate driving integrated circuits GDIC1-GDICn receives a gate high voltage VGH and a gate low voltage VGL as driving voltages, and are operated by gate clock signals GCLKs.

A first gate driving integrated circuit GDIC1 starts operation by a gate start signal GVST, and each of a second gate driving integrated circuit GDIC2 to the nth gate driving integrated circuit GDICn may receive gate signals GS1-GS(n−1) output from output terminal of previous gate driving integrated circuit as a start signal.

For example, a first gate signal GS1 output from the output terminal of the first gate driving integrated circuit GDIC1 corresponding to the first stage STG1 may be supplied to a first subpixel line SPL1 disposed in the first row and a start signal input terminal of the second gate driving integrated circuit GDIC2 of the second stage STG2.

Accordingly, the first gate driving integrated circuit GDIC1 of the first stage STG1 may use the gate start signal GVST as a start signal, but each of the second gate driving integrated circuit GDIC2 of the second stage STG2 to the nth gate driving integrated circuit GDICn of the nth stage STGn may use the gate signal output from the output terminal of the previous gate driving integrated circuit as a start signal.

Here, the expression that first gate signal GS1 output from the output terminal of the first gate driving integrated circuit GDIC1 is the first start signal START1 is to show that the first gate signal GS1 generated in the first stage STG1 is used as a start signal for the next stage.

Dependently connected stages and the configuration of using the gate signal of the previous stage as the start signal of the next stage may be applied equally to all stages STG1-STGn as shown in the relationship between the (n−1)th stage STG(n−1) and the nth stage STGn.

A gate signal output from one stage (one gate driving integrated circuit) may include one or more scan signals and one or more emission signals. For example, two scan signals and one emission signal may be generated from one stage (one gate driving integrated circuit).

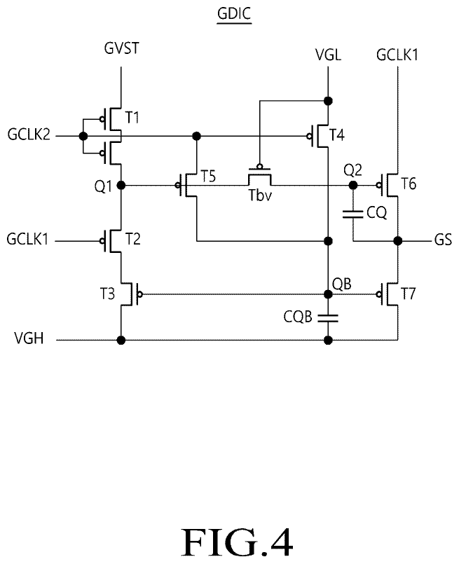

FIG. 4 illustrates an example of a gate driving integrated circuit according to embodiments of the present disclosure.

Referring to FIG. 4, the gate driving integrated circuit according to embodiments of the present disclosure may include first to seventh transistors T1-T7, an auxiliary transistor Tbv, a first capacitor CQ, and a second capacitor CQB.

The first transistor T1 may be switched according to the second gate clock signal GCLK2 to supply the start signal GVST to the Q1 node Q1. The first gate driving integrated circuit GDIC1 located in the first stage may receive a first gate start signal, and the second gate driving integrated circuit GDIC2 may receive a second gate start signal.

The second transistor T2 may be switched according to the first gate clock signal GCLK1 so that either the source electrode or the drain electrode of the second transistor T2 is electrically connected to the Q1 node Q1.

The third transistor T3 may be switched according to the potential of the QB node QB to supply the gate high voltage VGH to either the source electrode or the drain electrode of the second transistor T2.

The fourth transistor T4 may be switched according to the second gate clock signal GCLK2 to supply the gate low voltage VGL to the QB node QB.

The fifth transistor T5 may be switched according to the potential of the Q1 node Q1 to supply the second gate clock signal GCLK2 to the QB node QB.

The sixth transistor T6 may be an output buffer whose operation is controlled according to the potential of the Q2 node Q2. When the sixth transistor T6 may be activated when the Q2 node Q2 is the gate low voltage VGL to output a gate signal GS of the gate high voltage VGH to the output node N.

The auxiliary transistor Tbv may maintain a turned-on state by the gate low voltage VGL. The auxiliary transistor Tbv may maintain the voltages of the Q1 node Q1 and the Q2 node Q2 substantially the same.

The first capacitor CQ may be connected between the Q2 node Q2 and the output node N. The first capacitor CQ may store the voltage of the Q2 node Q2.

The second capacitor CQB may be connected between the QB node QB and the input terminal of the gate high voltage VGH. The second capacitor CQB may be store the voltage of the QB node QB.

The gate driving integrated circuit GDIC may be a scan driving integrated circuit generating a scan signal, or a emission driving integrated circuit generating an emission signal.

The display apparatus 100 of the present disclosure may include a plurality of display panels 110, and may independently control the viewing angle of each display panel 110.

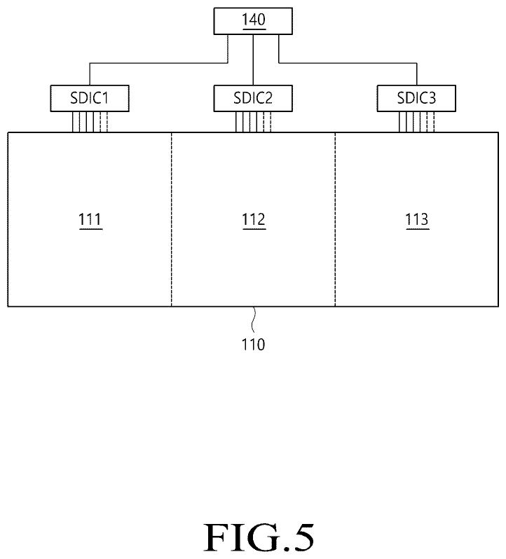

FIG. 5 illustrates a structure configured to drive a plurality of display panels according to embodiments of the present disclosure.

Referring to FIG. 5, the display apparatus 100 according to aspects of the present disclosure may include one or more display panels 111, 112, 113, a timing controller 140, and one or more source driving integrated circuits SDIC1, SDIC2, and SDIC3.

The one or more display panels may be at least one or more of the first display panel 111, the second display panel 112, and the third display panel 113. The first display panel 111 may be a dashboard display panel, the second display panel 112 may be a center fascia display panel, and the third display panel 113 may be a passenger display panel.

The first source driving integrated circuit SDIC1 may supply a first data voltage to the first display panel 111. The second source driving integrated circuit SDIC2 may supply a second data voltage to the second display panel 112. The third source driving integrated circuit SDIC3 may supply a third data voltage to the third display panel 113.

The timing controller 140 may receive external timing signals such as a vertical synchronization signal Vsync, a horizontal synchronization signal Hsync, a data enable signal DE and main clock MCLK, etc., and image data DATA from the host system through an interface such as low voltage differential signaling LVDS interface.

The timing controller 140 may generate control signals for the operation of the gate driving circuit 120 and the data driving circuit 130 based on the external timing signals, and supply the image data DATA to the source driving integrated circuits SDIC1-SDIC3 constituting the data driving circuit 130.

The timing controller 140 may receive coordinates of important information from the host system and calculate a checksum to check for errors in the image data DATA based on the coordinates of the important information.

When the display apparatus 100 displays vehicle-related information, the important information may be information configured to display vehicle warnings such as safety control off, temperature caution, anti-lock brake system (ABS), lack of hydraulic pressure, etc., but aspects of the present disclosure are not limited thereto.

The timing controller 140 transmits the coordinates and checksum of important information to the source driving integrated circuits SDIC1-SDIC3, respectively.

After this, the timing controller 140 may receive feedback on whether there is an error in the image data DATA from the source driving integrated circuits SDIC1-SDIC3 through a specific interface. Additionally, the timing controller 140 may also receive feedback on whether there is an error in the communication state from the source driving integrated circuits SDIC1-SDIC3.

Based on the feedback results, the timing controller 140 may determine whether an error has occurred in the communication state or an abnormal image is displayed in the source driving integrated circuits SDIC1-SDIC3.

Each source driving integrated circuit SDIC1-SDIC3 converts the image data DATA received from the timing controller 140 into an analog data voltage and supplies it to through data lines corresponding for the display panel 111-113.

The first source driving integrated circuit SDIC1 may supply the data voltage through a data line connected to the first display panel 111, the second source driving integrated circuit SDIC2 may supply the data voltage through a data line connected to the second display panel 112, and the third source driving integrated circuit SDIC3 may supply the data voltage through a data line connected to the third display panel 113.

First subpixels and second subpixels with different emission angles may be arranged together in at least one display panel 111-113. The display apparatus 100 may control the viewing angle of image by selectively controlling driving operations of the first subpixels or the second subpixels.

For above purpose, a plurality of unit subpixels (or a plurality of subpixels) may be disposed on the display area of each display panel 111 to 113.

The unit subpixel (or subpixel) may be a subpixel that emits light of a specified color. The unit subpixel may include a first subpixel with a first emission angle and a second subpixel with a second emission angle. The unit subpixel may be a unit subpixel that emits red color, a unit subpixel that emits green color, or a unit subpixel that emits blue color.

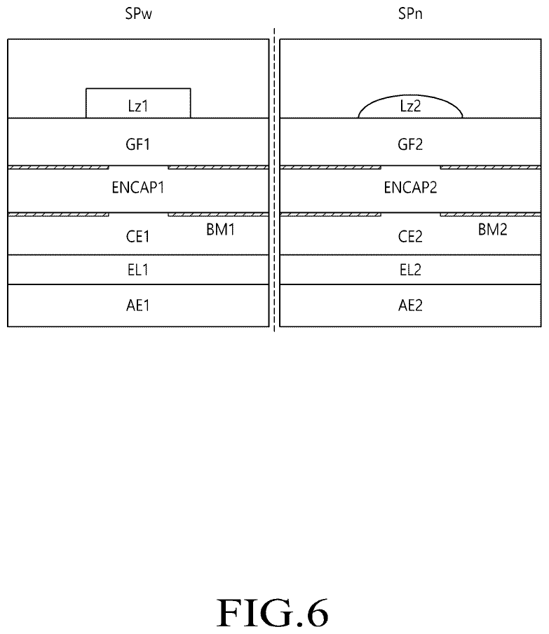

FIG. 6 is a cross-sectional diagram of a unit subpixel according to embodiments of the present disclosure.

Referring to FIG. 6, the unit subpixel disposed on the display panel 110 in the display apparatus 100 according to embodiments of the present disclosure may include a first subpixel SPw with a first emission angle and a second subpixel SPn with a second emission angle.

The first emission angle emitted through the first subpixel SPw may be greater than the second emission angle emitted through the second subpixel SPn.

The first subpixel SPw may include a first anode electrode AE1, a first emission layer EL1, and a first cathode electrode CE1. The first anode electrode AE1, the first emission layer EL1, and the first cathode electrode CE1 may constitute a first light emitting element.

Further, a first black matrix BM1, a first insulating layer ENCAP1, a first gap filler GF1, and a first lens Lz1 with a first emission angle may be disposed on the first cathode electrode CE1. An auxiliary gap filler may be further disposed on the first lens Lz1.

Here, a portion of the area of the first black matrix BM1 overlapping with the first anode electrode AE1 may be open.

The second subpixel SPn may include a second anode electrode AE2, a second emission layer EL2, and a second cathode electrode CE2. The second anode electrode AE2, the second emission layer EL2, and the second cathode electrode CE2 may constitute a second light emitting element.

Further, a second black matrix BM2, a second insulating layer ENCAP2, a second gap filler GF2, and a second lens Lz2 with a second emission angle may be disposed on the second cathode electrode CE2. An auxiliary gap filler may be further disposed on the second lens Lz2.

A portion of the area of the second black matrix BM2 overlapping with the second anode electrode AE2 may be open.

The first black matrix BM1 and the second black matrix BM2 may prevent light from being incident to an active layer of a driving transistor constituting a subpixel to prevent leakage current from being generated.

The first anode electrode AE1 of the first subpixel SPw and the second anode electrode AE2 of the second subpixel SPn may be formed in a same process, on a same layer, with a same material, and with a same thickness, but aspects of the present disclosure are not limited thereto. The first anode electrode AE1 and the second anode electrode AE2 may be formed through a mask process using photoresist, but aspects of the present disclosure are not limited thereto.

The first emission layer EL1 of the first subpixel SPw and the second emission layer EL2 of the second subpixel SPn may be formed with a same material, same color, and same thickness on a same layer through a same process, but aspects of the present disclosure are not limited thereto.

Each of the first emission layer EL1 and the second emission layer EL2 may include a hole injecting layer (HIL), a hole transporting layer (HTL), an electron blocking layer (EBL), an emitting material layer (EML), an electron transporting layer (ETL), a hole blocking layer HBL, and an electron injecting layer (EIL), but aspects of the present disclosure are not limited thereto.

The first cathode electrode CE1 of the first subpixel SPw and the second cathode electrode CE2 of the second subpixel SPn may be formed with the same material, same color, and same thickness on the same layer through a same process, but aspects of the present disclosure are not limited thereto.

The first cathode electrode CE1 and the second cathode electrode CE2 may be formed of an opaque metal material, such as at least one of aluminum (Al), tungsten (W), copper (Cu), molybdenum (Mo), chromium (Cr), tantalum (Ta), titanium (Ti), and alloys formed from combinations thereof, but aspects of the present disclosure are not limited thereto.

The first gap filler GF1 of the first subpixel SPw and the second gap filler GF2 of the second subpixel SPn may be formed with the same material, same color, and same thickness on the same layer through a same process, but aspects of the present disclosure are not limited thereto.

A space (or a distance) between the first emission layer EL1 and the first lens Lz1 may be adjusted based on the thickness (height) of the first gap filler GF1. Further, a space (or a distance) between the second emission layer EL2 and the second lens Lz2 may be adjusted based on the thickness (height) of the second gap filler GF2.

The first gap filler GF1 or the second gap filler GF2 may be formed of one of acrylic, epoxy, and silicon or combinations thereof. Further, the first gap filler GF1 or the second gap filler GF2 may be formed of an organic material, but aspects of the present disclosure are not limited thereto.

A particle size in the first gap filler GF1 or the second gap filler GF2 may be equal to a wavelength of light, or may be larger or smaller than the wavelength of light by a certain range. The first gap filler GF1 or the second gap filler GF2 may have forward diffusion property based on one of a particle density, a particle size, and a particle shape.

The first gap filler GF1 or the second gap filler GF2 may have a smaller refractive index than that of the first insulating layer ENCAP1. For example, the first gap filler GF1 and the second gap filler GF2 may have a smaller refractive index than that of the first insulating layer ENCAP1 due to one of the particle density, size, and shape.

A material of the first insulating layer ENCAP1 or the second insulating layer ENCAP2 may be one of TiO₂, Al₂O₃, and SiO₂, but aspects of the present disclosure are not limited thereto.

When the material of the first insulating layer ENCAP1 or the second insulating layer ENCAP2 is titanium oxide (TiO₂), the first insulating layer ENCAP1 or the second insulating layer ENCAP2 may have a refractive index in a range of 2.6 to 2.9. When the material of the first insulating layer ENCAP1 or the second insulating layer ENCAP2 is Al₂O₃, the first insulating layer ENCAP1 or the second insulating layer ENCAP2 may have a refractive index in a range of 1.75 to 1.76. When the material of the first insulating layer ENCAP1 or the second insulating layer ENCAP2 is silicon oxide (SiO₂), the first insulating layer ENCAP1 or the second insulating layer ENCAP2 may have a refractive index in a range of 1.40 to 1.55.

The first lens Lz1 disposed in the first subpixel SPw with a wide emission angle may be a cylinder-type lens, but aspects of the present disclosure are not limited thereto. The second lens Lz2 disposed in the second subpixel SPn with a narrow emission angle may be a circular type lens, but aspects of the present disclosure are not limited thereto.

The first lens Lz1 of the first subpixel SPw and the second lens Lz2 of the second subpixel SPn may be formed with a same material, same color, and same thickness on the same layer through a same process, but aspects of the present disclosure are not limited thereto. For example, the first lens Lz1 and the second lens Lz2 may be formed to have different shapes and different sizes.

The refractive index of the first lens Lz1 and the second lens Lz2 may be determined depending on the shape of the lens and the thickness (height) of the first gap filler GF1 and the second gap filler GF2.

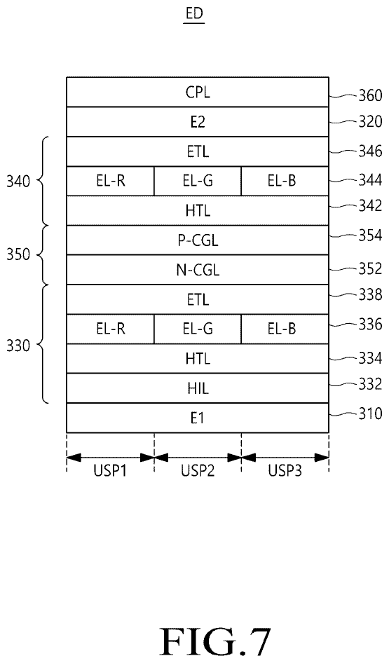

FIG. 7 illustrates a light emitting element according to embodiments of the present disclosure.

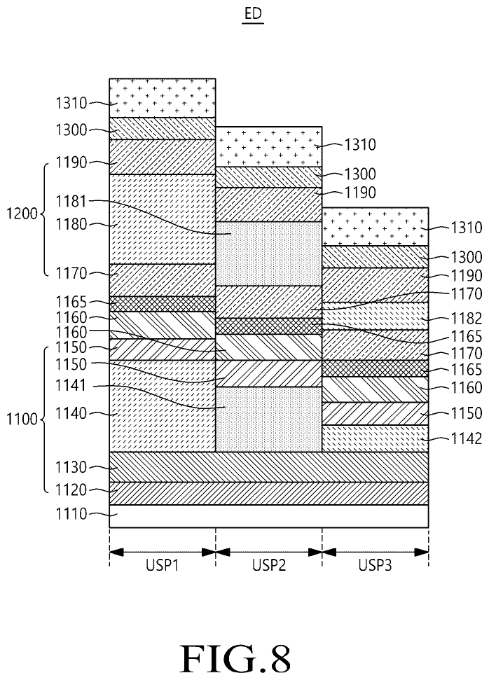

Referring to FIG. 7, the light emitting element ED of the subpixel in the display apparatus 100 according to embodiments of the present disclosure may include a first electrode 310 and a second electrode 320. Further, the light emitting element ED may include a first emission part 330, a second emission part 340 and a charge generation layer 350 between the first electrode 310 and the second electrode 320. The description included in FIG. 7 may be included in the description included in FIG. 8.

The first electrode 310 as an anode electrode may include a conductive material with a high work function, but aspects of the present disclosure are not limited thereto. The second electrode 320 as a cathode electrode may include a conductive material with a low work function, but aspects of the present disclosure are not limited thereto.

The first emission part 330 may include a hole injecting layer 332, a first hole transporting layer 334, a first emission layer 336, and a first electron transporting layer 338, but aspects of the present disclosure are not limited thereto.

The hole injecting layer 332 may be disposed between the first electrode 310 and the first emission layer 336. For example, the hole injecting layer 332 may include at least one of MTDATA (4,4′,4″-tris(N-3-methylphenyl-N-phenylamino)triphenylamine), CuPc (copper phthalocyanine), and TCTA (tris(4-carbazoyl-9-ylphenyl)amine), NPB(N,N′-di(naphthalen-1-yl)-N,N′-diphenyl-benzidine), NPD(N,N-dinaphthyl-N,N′-diphenyl benzidine), HATCN(1,4,5,8,9,11-hexaazatriphenylene-hexanitrile), TDAPB(1,3,5-tris(4-diphenylaminophenyl)benzene), PEDOT/PSS(Poly(3,4-ethylene dioxythiophene)/Polystyrene sulfonate), F4TCNQ(2,3,5,6-tetrafluoro-7,7,8,8-tetracyanl-quinidimethane), N-(biphenyl-4-yl)-9,9-dimethyl-N-4-(9-phenyl-9H-carbazol-3-yl)phenyl)-9H-fluoren-2-amine, but aspects of the present disclosure are not limited thereto.

The first hole transporting layer 334 may be disposed between the hole injecting layer 332 and the first emission layer 336. The first emission layer 336 may be disposed between the first hole transporting layer 334 and the first electron transporting layer 338. Further, the first electron transporting layer 338 may be disposed between the first emission layer 336 and a charge generation layer 350.

The second emission part 340 may include a second hole transporting layer 342, a second emission layer 344, and a second electron transporting layer 346, but aspects of the present disclosure are not limited thereto.

The second emission layer 344 may be disposed between the second hole transporting layer 342 and the second electron transporting layer 346. The second electron transporting layer 346 may be disposed between the second emission layer 344 and the second electrode 320.

The electron injecting layer may be further disposed between the second electron transporting layer 346 and the second electrode 320. The electron injecting layer may include an alkali halide compound, e.g., LiF, CsF, NaF or BaF₂, or lithium quinolate (Liq), lithium benzoate or sodium stearate, e.g., but is not limited thereto.

Each of the first emission layer 336 and the second emission layer 344 may be formed by doping a host with a dopant, and may emit the same color or different colors.

For example, the first emission layer 336 and the second emission layer 344 may include a red emission layer EL-R, a green emission layer EL-G, and a blue emission layer EL-B, respectively. The red emission layer EL-R may form a first subpixel area USP1 that emits red color. The green emission layer EL-G may form a second subpixel area USP2 that emits green color. The blue emission layer EL-B may form a third subpixel area USP3 that emits blue color.

The first hole transporting layer 334 and the second hole transporting layer 342 may be formed of the same material or may be formed of different materials.

The first electron transporting layer 338 and the second electron transporting layer 346 may be formed of oxadiazole, triazole, phenanthroline, benzoxazole, benzthiazole or benzimidazole (e.g., 2-[4-(9,10-Di-2-naphthalenyl-2-anthracenyl)phenyl]-1-phenyl-1H-benzimidazole), but are not limited thereto.

Each of the first electron transporting layer 338 and the second electron transporting layer 346 may include a dopant such as an alkali metal or an alkaline earth metal, but are not limited thereto. The first electron transporting layer 338 and the second electron transporting layer 346 may be formed of the same material or may be formed of different materials.

A charge generation layer (CGL) 350 may be disposed between the first emission part 330 and the second emission part 340. The charge generation layer 350 may be disposed between the emission parts to supply positive and negative charges to each emission part, respectively.

The charge generation layer 350 may include an N-type charge generation layer (N-CGL) 352 adjacent to the first emission part 330 and a P-type charge generation layer (P-CGL) 354 adjacent to the second emission part 340. The N-type charge generation layer 352 may supply electrons to the first emission part 330, and the P-type charge generation layer 354 may supply holes to the second emission part 340.

The N-type charge generation layer 352 may be an organic layer doped with an alkali metal such as Li, Na, K, Cs, and/or an alkaline earth metal such as Mg, Sr, Ba, and Ra, but are not limited thereto.

The second hole injecting layer may be further disposed between the P-type charge generation layer 354 and the second hole transporting layer 342 or between the N-type charge generation layer 352 and the P-type charge generation layer 354. When forming the second hole injecting layer, holes generated in the P-type charge generation layer 354 may be efficiently injected and transferred to the second emission part 340.

The first hole injecting layer 332 and the second hole injecting layer may be formed of the same material or may be formed of different materials.

A capping layer 360 may be formed on the second electrode 320 to increase the light extraction effect of the light emitting element ED. The capping layer 360 may be formed of any one of the materials constituting the first and second hole transporting layers 334, 342, or the materials constituting the first and second electron transporting layers 338, 346, but aspects according to the present disclosure are not limited thereto. As another example, the capping layer 360 may be formed of any one of the host materials of the first emission part 336 and the second emission part 344, but aspects of the present disclosure are not limited thereto. In another example, the capping layer 360 may be omitted.

A light emitting element ED with a tandem structure may lower the driving voltage and emit white color. Therefore, the display apparatus 100 may be driven at a low voltage, improve a life span of the light emitting element ED, and improve an emission efficiency.

When a step is not formed in the charge generation layer 350 and adjacent subpixels are connected in the display apparatus 100 of the present disclosure, a horizontal current may be generated from the highly conductive charge generation layer 350 to the adjacent subpixel. Thus, light leakage may occur where unwanted subpixels emit light together.

On the other hand, when the charge generation layer 350 is formed with a step (or distance), horizontal current may be prevented from occurring due to the high conductivity of the charge generation layer 350. Thus, it is possible to prevent light leakage from occurring where unwanted adjacent subpixels emit light together.

FIG. 8 illustrates another example of a light emitting element in a display apparatus according to embodiments of the present disclosure.

Referring to FIG. 8, the light emitting element ED of the display apparatus 100 according to embodiments of the present disclosure may include emission parts 1100, 1200 between the first electrode 1110 and the second electrode 1300. The description included in FIG. 8 may be included in the description included in FIG. 7

The first electrode 1110 may include an indium-tin-oxide (ITO), and a silver alloy (Ag alloy), but not limited thereto. For example, ITO may be formed to a thickness of 70 Å, a silver alloy (Ag alloy) may be formed on top (or an upper portion) of the ITO to a thickness of 1000 Å, and then ITO may be formed on top of the silver alloy to a thickness of 70 Å, but aspects of the present disclosure are not limited thereto.

The first emission part 1100 may be disposed on the first electrode 1110. The first emission part 1100 may include a hole injecting layer 1120, a first hole transporting layer 1130, an emission layer, and a first electron transporting layer 1150, but aspects of the present disclosure are not limited thereto.

The hole injecting layer 1120 may be formed on the first electrode 1110. The hole injecting layer 1120 may be formed of HATCN (1,4,5,8,9,11-hexaazatriphenylene-hexanitrile), etc., but aspects of the present disclosure are not limited thereto. For example, the hole injecting layer 1120 may be formed to a thickness of 70 Å, but aspects of the present disclosure are not limited thereto. The first hole transporting layer 1130 may be formed on the hole injecting layer 1120. The first hole transporting layer 1130 may be formed of NPD (N,N-dinaphthyl-N,N′-diphenylbenzidine), etc., but aspects of the present disclosure are not limited thereto. For example, the first hole transporting layer 1130 may be formed to a thickness of 500 Å, but aspects of the present disclosure are not limited thereto.

The 1-1 emission layer 1140 may be disposed in the red subpixel area USP1 on the first hole transporting layer 1130. The 1-1 emission layer 1140 may include at least one host and at least one dopant. For example, the host material may be composed of a beryllium compound (Be complex) derivative, etc., but aspects of the present disclosure are not limited thereto. For example, after forming the host material to a thickness of 650 Å, the 1-1 emission layer 1140 may be formed by doping with a dopant at a level of 5%, but the aspects of the present disclosure are not limited thereto.

The 1-2 emission layer 1141 may be disposed in the green subpixel area USP2 on the first hole transporting layer 1130. The 1-2 emission layer 1141 may include at least one host and at least one dopant. For example, the host material may be composed of CBP (carbazole biphenyl), etc., but aspects of the present disclosure are not limited thereto. For example, after forming the host material to a thickness of 400 Å, the 1-2 emission layer 1141 may be formed by doping with a dopant at a level of 5%, but the aspects of the present disclosure are not limited thereto.

The 1-3 emission layer 1142 may be disposed in the blue subpixel area USP3 on the first hole transporting layer 1130. The 1-3 emission layer 1142 may include at least one host and at least one dopant. For example, the host material may be composed of an anthracene derivative, etc., but aspects of the present disclosure are not limited thereto. For example, after forming the host material to a thickness of 200 Å, the 1-3 emission layer 1142 may be formed by doping with a dopant at a level of 5%, but aspects of the present disclosure are not limited thereto.

For example, the thickness of the 1-1 emission layer 1140 may be thicker than the thickness of the 1-2 emission layer 1141. For example, the thickness of the 1-1 emission layer 1140 may be thicker than the thickness of the 1-3 emission layer 1142. For example, the thickness of the 1-2 emission layer 1141 may be thicker than the thickness of the 1-3 emission layer 1142. For example, the thickness of the 1-1 emission layer 1140 may be thicker than the thickness of each of the 1-2 emission layer 1141 and the 1-3 emission layer 1142.

The first electron transporting layer 1150 may be disposed on the 1-1 emission layer 1140, the 1-2 emission layer 1141, and the 1-3 emission layer 1142. For example, the first electron transporting layer 1150 may include an anthracene derivative and lithium quinolate (Liq), but aspects of the present disclosure are not limited thereto. For example, an anthracene derivative and Liq (lithium quinolate) may be mixed in a ratio of 1:1, but aspects of the present disclosure are not limited thereto. The first electron transporting layer 1150 may be formed to a thickness of 70 Å, but aspects of the present disclosure are not limited thereto.

For another example, a hole blocking layer may be further formed under the first electron transporting layer 1150. The hole blocking layer may be formed on the 1-1 emission layer 1140, the 1-2 emission layer 1141, and the 1-3 emission layer 1142.

An N-type charge generation layer (N-CGL) 1160 may be formed on the first electron transporting layer 1150, and a P-type charge generation layer (P-CGL) 1165 may be formed on the N-type charge generation layer 1160. The N-type charge generation layer 1160 may be formed of Alq₃, etc., but embodiments of the present disclosure are not limited thereto. For example, the N-type charge generation layer 1160 may be formed to a thickness of 100 Å and then doped with lithium (Li), but aspects of the present disclosure are not limited thereto. The P-type charge generation layer 1165 may be formed on the N-type charge generation layer 1160 by HATCN, etc., but aspects of the present disclosure are not limited thereto. The P-type charge generation layer 1165 may be formed to a thickness of 100 Å to form a charge generation layer with a thickness of 200 Å, but aspects of the present disclosure are not limited thereto.

The second emission part 1200 may be disposed on the charge generation layer. The second emission part 1200 may include a second hole transporting layer 1170, an emission layer, and a second electron transporting layer 1190, but aspects of the present disclosure are not limited thereto. For example, the charge generation layer may be disposed between the first emission part 1100 and the second emission part 1200.

A second hole transporting layer 1170 may be formed on the charge generation layer. The second hole transporting layer 1170 may be formed of NPD or the like, but aspects of the present disclosure are not limited thereto. The second hole transporting layer 1170 may be formed to a thickness of 400 Å, but aspects of the present disclosure are not limited thereto. For example, the thickness of the second hole transporting layer 1170 may be greater than or equal to the thickness of the first hole transporting layer 1130, but aspects of the present disclosure are not limited thereto.

The 2-1 emission layer 1180 may be formed in the red subpixel area USP1 on the second hole transporting layer 1170. The 2-1 emission layer 1180 may include at least one host and at least one dopant. The 2-1 emission layer 1180 may be composed of a host material, such as a beryllium compound (Be complex) derivative, but aspects of the present disclosure are not limited thereto. The host material may be formed to a thickness of 650 Å and then doped with a dopant at a level of 5% to form the 2-1 emission layer 1180, but aspects of the present disclosure are not limited thereto.

In another example, a hole transporting layer may be further disposed under the 2-1 emission layer 1180. The hole transporting layer may further improve an emission efficiency of the 2-1 t emission layer 1180. The hole transporting layer may be disposed between the second hole transporting layer 1170 and the 2-1 emission layer 1180. For example, the hole transporting layer may be formed of the same material as the second hole transporting layer 1170, but aspects of the present disclosure are not limited thereto. For example, the thickness of the hole transporting layer may be thicker than the thickness of the second hole transporting layer 1170, but aspects of the present disclosure are not limited thereto.

The 2-2 emission layer 1181 may be formed in the green subpixel area USP2 on the second hole transporting layer 1170. The 2-2 emission layer 1181 may include at least one host and at least one dopant. The 2-2 emission layer 1181 may be composed of a host material such as CBP, but aspects of the present disclosure are not limited thereto. The host material may be formed to a thickness of 400 Å and then doped with a dopant at a level of 5% to form the 2-2 emission layer 1181, but aspects of the present disclosure are not limited thereto.

The 2-3 emission layer 1182 may be formed in the blue subpixel area USP3 on the second hole transporting layer 1170. The 2-3 emission layer 1182 may include at least one host and at least one dopant. The 2-3 emission layer 1182 may include an anthracene derivative as a host material, but aspects of the present disclosure are not limited thereto. The host material may be formed to a thickness of 200 Å and then doped with a dopant at a level of 5% to form the 2-3 emission layer 1182, but aspects of the present disclosure are not limited thereto.

For example, the thickness of the 2-1 emission layer 1180 may be thicker than the thickness of the 2-2 emission layer 1181. For example, the thickness of the 2-1 emission layer 1180 may be thicker than the thickness of the 2-3 emission layer 1182. For example, the thickness of the 2-2 emission layer 1181 may be thicker than the thickness of the 2-3 emission layer 1182. For example, the thickness of the 2-1 emission layer 1180 may be thicker than each of the 2-2 emission layer 1181 and the 2-3 emission layer 1182.

For example, the thickness of the 1-1 emission layer 1140 may be the same as or different from the thickness of the 2-1 emission layer 1180. For example, the thickness of the 1-2 emission layer 1141 may be the same as or different from the thickness of the 2-2 emission layer 1181. For example, the thickness of the 1-3 emission layer 1142 may be the same as or different from the thickness of the 2-3 emission layer 1182.

A second electron transporting layer 1190 may be formed on the 2-1 emission layer 1180, the 2-2 emission layer 1181, and the 2-3 emission layer 1182. The second electron transporting layer 1190 may be composed of an anthracene derivative, lithium quinolate (Liq), etc., but aspects of the present disclosure are not limited thereto. For example, an anthracene derivative and Liq (lithium quinolate) may be mixed at a ratio of 1:1 to form a thickness of 300 Å, but aspects of the present disclosure are not limited thereto. For example, the thickness of the second electron transporting layer 1190 may be greater than or equal to the thickness of the first electron transporting layer 1150, but aspects of the present disclosure are not limited thereto.

For example, the emission layer of the first emission part 1100 may emit a same color as the emission layer of the second emission part 1200. For example, the 1-1 emission layer 1140 of the first emission part 1100 may emit the same color as the 2-1 emission layer 1180 of the second emission part 1200. For example, the 1-2 emission layer 1141 of the first emission part 1100 may emit the same color as the 2-2 emission layer 1181 of the second emission part 1200. For example, the 1-3 emission layer 1142 of the first emission part 1100 may emit the same color as the 2-3 emission layer 1182 of the second emission part 1200.

For another example, a hole blocking layer may be further formed under the second electron transporting layer 1190. The hole blocking layer may be formed on the 2-1 emission layer 1180, the 2-2 emission layer 1181, and the 2-3 emission layer 1182.

The second electrode 1300 may be formed on the second electron transporting layer 1190. For example, the second electrode 1300 may be formed of magnesium (Mg), silver (Ag), etc., but aspects of the present disclosure are not limited thereto. For example, a magnesium-silver alloy (Mg:Ag) obtained by mixing magnesium (Mg) and silver (Ag) at a ratio of 9:1 may be formed to a thickness of 140 Å, but aspects of the present disclosure are not limited thereto. The second electrode 1300 may be a semi-transmissive electrode.

A capping layer 1310 may be formed on the second electrode 1300. The capping layer 1310 may be composed of one or more layers, but aspects of the present disclosure are not limited thereto. The capping layer 1310 may minimize damage to the second electrode 1300 of the light emitting element ED and the organic material layers below the second electrode 1300 from an external light source. The capping layer 1310 may be formed of an organic or inorganic film. The capping layer 1310 may be an inorganic layer formed of a material such as LiF, and may further include an organic layer, but aspects of the present disclosure are not limited thereto. For example, the capping layer 1310 may be composed of a stacked structure of an organic film and an inorganic film, and the thickness of the organic film may be different from the thickness of the inorganic film. For example, the thickness of the organic film may be greater than the thickness of the inorganic film. As another example, the capping layer 1310 may be composed of two or more layers by stacking materials with different refractive indices. Thus, the emission efficiency of the display apparatus 100 may be improved.

Considering the step between subpixels of the light emitting element ED based on the first electrode 1110, the step between the 1-1 emission layer 1140 and the 1-2 emission layer 1141 may be formed at a level of 250 Å, the step between the 1-2 emission layer 1141 and the 1-3 emission layer 1142 may be formed at a level of 200 Å. Further, the step between the 1-3 emission layer 1142 and the 1-1 emission layer 1140 may be formed at a level of 450 Å.

In the light emitting element ED of the present disclosure, since the step between the 1-1 emission layer 1140 and the 1-2 emission layer 1141, the step between the 1-2 emission layer 1141 and the 1-3 emission layer 1142, and the step between the 1-3 emission layer 1142 and the 1-1 emission layer 1140 is formed, the charge generation layers 1160 may have steps with each other in the red, green, and blue subpixel areas of the upper part of the emission layer. For example, in the light emitting element ED of the present disclosure, since the step between the 1-1 emission layer 1140 and the 1-2 emission layer 1141, the step between the 1-2 emission layer 1141 and the 1-3 emission layer 1142 and the step between the 1-3 light emitting layer 1142 and the 1-1 light emitting layer 1140 are all formed at a level of 200 Å or more, the charge generation layers 1160 formed in the red, green, and blue subpixel areas on the emission layer also have a step of 200 Å or more.

Accordingly, the charge generation layer 1160 in the red subpixel area USP1, the charge generation layer 1160 in the green subpixel area USP2, and the charge generation layer 1160 in the blue subpixel area USP3 may not be substantially connected to each other. The meaning that the charge generation layers 1160 are not substantially connected between two subpixel areas may mean that the charge generation layers 1160 formed in each subpixel area are separated by the step or horizontal current hardly flows even if the charge generation layers 1160 formed in each subpixel area are not separated by the step. Accordingly, the charge generation layers 1160 may be substantially insulated with each other by the step.

The light emitting element ED constituting the display apparatus 100 of the present disclosure does not generate horizontal current due to the high conductivity of the charge generation layer 1160. Therefore, a light leakage phenomenon in which unwanted adjacent subpixels emit light together may be reduced.

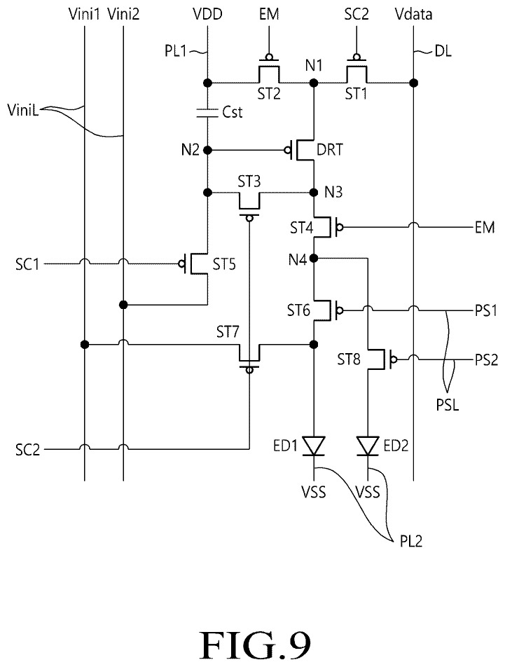

FIG. 9 illustrates a circuit diagram of a unit subpixel according to embodiments of the present disclosure.

Referring to FIG. 9, a unit subpixel in the display apparatus 100 according to aspects of the present disclosure may include a first light emitting element ED1, a second light emitting element ED2, a driving transistor DRT, and an internal compensation circuit.

The first light emitting element ED1 may be disposed in the first subpixel SPw, and the second light emitting element ED2 may be disposed in the second subpixel SPn.

The first lens Lz1 may be disposed on the first light emitting element ED1, and the second lens Lz2 may be disposed on the second light emitting element ED2.

The switching transistors ST1-ST8, DRT disposed in unit subpixel may be implemented as PMOS type LTPS (Low Temperature Poly Silicon) transistors, and a desired response characteristics may be obtained from these, but aspects of the present disclosure are not limited thereto.

For example, at least one transistor among the switching transistors ST1-ST8 may be implemented as an NMOS type or PMOS type oxide transistor with good characteristics for leakage current when turned off, and the remaining transistors may be implemented as a PMOS type LTPS transistor with good response characteristics, but aspects of the present disclosure are not limited thereto.

The unit subpixel may include a first switching transistor ST1 which is connected to the data line and transmits the data voltage Vdata according to the second scan signal SC2.

The unit subpixel may include a second switching transistor ST2 which is connected to a first pixel voltage line PL1 supplying a pixel driving voltage VDD and transmits the pixel driving voltage VDD according to the emission signal EM.

The driving transistor DRT may connect the first node N1 to the third node N3. The driving transistor DRT may receive the voltage charged in the storage capacitor Cst as a gate voltage through the second node N2. The first node N1 may be shared by the first switching transistor ST1 and the second switching transistor ST2.

A fourth switching transistor ST4 may be connected between the third node N3 and the first light emitting element ED1. The fourth switching transistor ST4 may be controlled by the emission signal EM. A sixth switching transistor ST6 may be connected between the fourth node N4 and the first light emitting element ED1. The sixth switching transistor ST6 may be controlled by the first mode control signal PS1.

The fourth switching transistor ST4 may be connected between the third node N3 and the second light emitting element ED2. The fourth switching transistor ST4 may be controlled by the emission signal EM. An eighth switching transistor ST8 may be connected to the fourth node N4. The eighth switching transistor ST8 may be controlled by the second mode control signal PS2.

Accordingly, the first light emitting element ED1 or the second light emitting element ED2 may emit light by the first mode control signal PS1 and the second mode control signal PS2 in a state in which the fourth transistor T4 is turned on by the emission signal EM.

The third switching transistor ST3 may connect the second node N2 to the third node N3. The third switching transistor ST3 may be controlled by the second scan signal SC2.

The fifth switching transistor ST5 may be connected between the second node N2 and the initialization voltage line ViniL. The initialization voltage line ViniL may supply a second initialization voltage Vini2. The fifth switching transistor ST5 may be controlled by the first scan signal SC1. Accordingly, the fifth switching transistor ST5 may initialize the gate node of the driving transistor DRT to the second initialization voltage Vini2 by the first scan signal SC1.

The seventh switching transistor ST7 may be connected between an anode electrode of the first light emitting element ED1 and the initialization voltage line ViniL. The initialization voltage line ViniL may supply a first initialization voltage Vini1. The seventh switching transistor ST7 may be controlled by the second scan signal SC2. Accordingly, the seventh switching transistor ST7 may initialize the anode electrode of the first light emitting element ED1 to the first initialization voltage Vini1 by the second scan signal SC2.

The first light emitting element ED1 and the second light emitting element ED2 may emit light with an amount of current controlled by the voltage Vgs between the gate node and source node of the driving transistor DRT.

The first light emitting element ED1 may be connected to the driving transistor DRT through the fourth switching transistor ST4 and the sixth switching transistor ST6. The second light emitting element ED2 may be connected to the driving transistor DRT through the fourth switching transistor ST4 and the eighth switching transistor ST8.

The cathode electrodes of the first light emitting element ED1 and the second light emitting element ED2 may be connected to a second pixel voltage line PL2 supplying the low-potential pixel driving voltage VSS.

The driving transistor DRT may control a driving current flowing through the first light emitting element ED1 or the second light emitting element ED2 according to the voltage Vgs between the gate node and the source node.

The compensation circuit may sample the voltage Vgs between the gate node and the source node of the driving transistor DRT to compensate for the change in threshold voltage of the driving transistor DRT. The compensation circuit may include first to eighth switching transistors ST1-ST8 and a storage capacitor Cst. Alternatively, the remainder excluding the first switching transistor ST1 for supplying the data voltage Vdata may be referred to as the compensation circuit.

Accordingly, the unit subpixel constituting the display apparatus 100 of the present disclosure may control the first light emitting element ED1 by the first mode control signal PS1 and may control the second light emitting element ED2 by the second mode control signal PS2.

For example, the first mode control signal PS1 may supplied at a turn-on level (e.g., low level), and the second mode control signal PS2 may be supplied at a turn-off level (e.g. high level) in a period when the first light emitting element ED1 emits light.

The gate driving circuit 120 may be implemented in the form of a gate in panel (GIP) formed directly in the non-display area NDA of the display panel 110, or may be implemented in the form of a gate in array formed in the display area DA of the display panel 110.

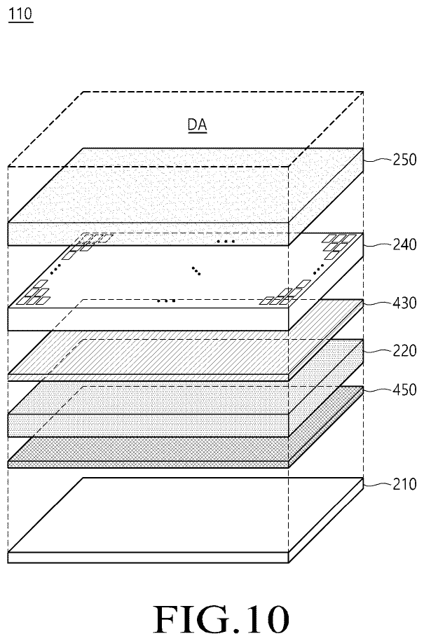

FIG. 10 illustrates a display panel with a structure of gate in array according to embodiments of the present disclosure.

Referring to FIG. 10, the display panel 110 according to aspects of the present disclosure may include a substrate 210, a base circuit layer 220, a pixel layer 240, and an encapsulation layer 250.

The pixel layer 240 may be a layer in which a plurality of subpixels SP are disposed and may be disposed on the substrate 210. The pixel layer 240 may include a plurality of subpixels SP disposed in the display area DA where an image is displayed.

The base circuit layer 220 may be a layer in which the gate driving circuit 120 is disposed as a gate in array type. The base circuit layer 220 may be disposed between the substrate 210 and the pixel layer 240. The base circuit layer 220 may include a gate driving circuit 120 of the gate in array type.

For example, the base circuit layer 220 may include a plurality of gate driving integrated circuits GDIC arranged in the entire area of the display area DA. For another example, the base circuit layer 220 may include a plurality of gate driving integrated circuits GDIC arranged in at least one partial area of the display area DA.

The base circuit layer 220 may include a gate voltage line configured to transmit a gate high voltage VGH or a gate low voltage VGL to the gate driving integrated circuit GDIC. In addition, the base circuit layer 220 may include a control signal line for supplying a control signal to control the gate driving integrated circuit GDIC.

For another example, two or more pixel voltage lines supplying two or more pixel driving voltages to the pixel layer 240 may be further disposed on the base circuit layer 220. In other words, the base circuit layer 220 may further include two or more pixel voltage lines configured to supply two or more pixel driving voltages to the pixel layer 240.

For example, two or more pixel driving voltages may include a high-potential pixel driving voltage and a low-potential pixel driving voltage supplied to the pixel layer 240, but aspects of the present disclosure are not limited thereto. The two or more pixel voltage lines may include a high-potential pixel voltage line and a low-potential pixel voltage line. Two or more pixel voltage lines may be electrically connected to patterns (e.g., metals) in the pixel layer 240.

The encapsulation layer 250 may be disposed on the pixel layer 240. The encapsulation layer 340 may prevent the organic layer disposed in the pixel layer 240 from being exposed to moisture or oxygen. Touch electrodes TE may be further disposed on the encapsulation layer 340.

The gate driving circuit 120 in the display apparatus 100 according to aspects of the present disclosure may be disposed in the display area DA, thereby significantly reducing a size of the non-display area NDA.

In addition, the pixel voltage line and the gate voltage line may be disposed in the display area DA in the display apparatus 100 according to aspects of the present disclosure, thereby further reducing the size of the non-display area NDA.

The display panel 110 according to aspects of the present disclosure may include a first shielding layer 430 disposed between the base circuit layer 220 and the pixel layer 240.

The first shielding layer 430 may shield the electric field between the base circuit layer 220 and the pixel layer 240. Accordingly, the base circuit layer 220 and the pixel layer 240 may reduce unwanted electrical effects on each other.

The first shielding layer 430 may be electrically connected to the pixel voltage line located in the pixel layer 240 to increase shielding effect.

For example, the first shielding layer 430 may be electrically connected to a first pixel voltage line among two or more pixel voltage lines located in the pixel layer 240. The first pixel voltage line may be a high-potential pixel voltage line transmitting a high-potential pixel driving voltage to the pixel layer 240.

For another example, the first shielding layer 430 may be electrically connected to a second pixel voltage line among two or more pixel voltage lines located in the pixel layer 240. The second pixel voltage line may be a low-potential pixel voltage line transmitting a low-potential pixel driving voltage to the pixel layer 240.

The first shielding layer 430 may be electrically connected to a source electrode or a drain electrode of the driving transistor disposed in the pixel layer 240. For example, the first shielding layer 430 may be electrically connected to the light emitting element, and the source electrode or drain electrode of the driving transistor included in each of the plurality of subpixels SP.

The first shielding layer 430 may be formed of a single layer or may be formed of a plurality of layers disposed on different layers, but aspects of the present disclosure are not limited thereto.

The display panel 110 according to aspects of the present disclosure may include a second shielding layer 450 disposed between the base circuit layer 220 and the substrate 210.

The second shielding layer 450 may shield the electric field between the base circuit layer 220 and the substrate 240. Additionally, the second shielding layer 450 may reduce electrical influence between signal lines of the gate driving integrated circuit GDIC disposed in the base circuit layer 220.

The second shielding layer 450 may be electrically connected to a gate voltage line disposed in the base circuit layer 220 to increase shielding effect.

For example, the second shielding layer 450 may be electrically connected to a first gate voltage line among two or more gate voltage lines located in the base circuit layer 220. The first gate voltage line may be a high-potential gate voltage line transmitting a gate high voltage to the base circuit layer 220.

For another example, the second shielding layer 450 may be electrically connected to a second gate voltage line among two or more gate voltage lines located in the base circuit layer 220. The second gate voltage line may be a low-potential gate voltage line transmitting a gate low voltage to the base circuit layer 220.

The display apparatus 100 of the present disclosure may reduce parasitic capacitance formed between the base circuit layer 220 and the pixel layer 240 through the first shielding layer 430 in the gate in array (or GIP) structure in which the base circuit layer 220 including the gate driving circuit 120 and the pixel layer 240 including subpixels SP are disposed in the display area DA. Additionally, the display apparatus 100 of the present disclosure may reduce the influence of parasitic capacitance formed between signal lines of the gate driving circuit 120 through the second shielding layer 450.

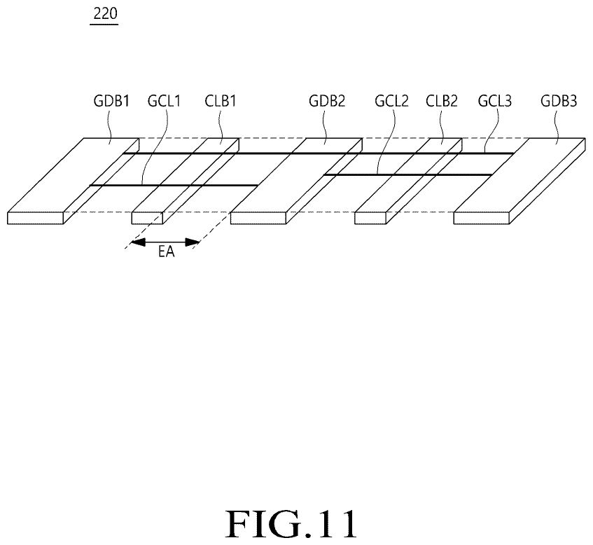

FIG. 11 illustrates a structure of a base circuit layer according to embodiments of the present disclosure.

Referring to FIG. 11, the base circuit layer 220 in which the gate driving circuit 120 is formed as a gate in array (or GIP) type in the display panel 110 according to aspects of the present disclosure may be disposed in the display area DA.

The base circuit layer 220 may be disposed in the display area DA and may be disposed below the pixel layer 240.

The base circuit layer 220 may include at least one or more gate circuit areas GDB1, GDB2, GDB3 and at least one control line areas CLB1, CLB2.

The gate circuit areas GDB1, GDB2, GDB3 may be areas where gate driving integrated circuits GDIC are disposed, and the control line areas CLB1, CLB2 may be areas where control signal lines transmitting control signals are disposed.

One gate driving integrated circuit GDIC may be disposed in one gate circuit area, or may be distributed (or divided) into a plurality of gate circuit areas. A plurality of gate circuit areas may be electrically connected through at least one gate connection line.

When one gate driving integrated circuit GDIC is distributed and disposed in a plurality of gate circuit areas GDB1, GDB2, GDB3, a plurality of transistors and capacitors constituting the gate driving integrated circuit GDIC may be distributed and disposed in the plurality of gate circuit areas GDB1, GDB2, GDB3.

For example, the gate driving integrated circuit GDIC of FIG. 4 may be distributed and disposed in the first gate circuit area GDB1, the second gate circuit area GDB2, and the third gate circuit area GDB3. In this case, the first portion of the gate driving integrated circuit GDIC may be disposed in the first gate circuit area GDB1, the second portion of the gate driving integrated circuit GDIC may be disposed in the second gate circuit area GDB2, and a third portion of the gate driving integrated circuit GDIC may be disposed in the third gate circuit area GDB3.

The first portion of the gate driving integrated circuit GDIC disposed in the first gate circuit area GDB1 may include transistors (e.g., Tbv, T6) connected to the Q2 node Q2 and the first capacitor CQ.

The second portion of the gate driving integrated circuit GDIC disposed in the second gate circuit area GDB2 may include transistors (e.g., T3, T4, T7) connected to the QB node QB and the second capacitor CQB.

The third portion of the gate driving integrated circuit GDIC disposed in the third gate circuit area GDB3 may include transistors (e.g., T1, T2, T5) connected to the Q1 node Q1.

In this case, the first portion of the gate driving integrated circuit GDIC disposed in the first gate circuit area GDB1 may be electrically connected to the second portion of the gate driving integrated circuit GDIC disposed in the second gate circuit area GDB2 through a first gate connection line GCL1. In addition, the second portion of the gate driving integrated circuit GDIC disposed in the second gate circuit area GDB2 may be electrically connected to the third portion of the gate driving integrated circuit GDIC disposed in the third gate circuit area GDB3 through a second gate connection line GCL2. In addition, the first portion of the gate driving integrated circuit GDIC disposed in the first gate circuit area GDB1 may be electrically connected to the third portion of the gate driving integrated circuit GDIC disposed in the third gate circuit area GDB3 through a third gate connection line GCL3.

The gate voltage line configured to supply the gate high voltage VGH or the gate low voltage VGL to the gate driving integrated circuit GDIC may be disposed in the gate circuit areas GDB1, GDB2, GDB3.

Control line areas CLB1, CLB2 including control signal lines may be located between the gate circuit areas GDB1, GDB2, GDB3.

The control signal lines supplying the control signals to the plurality of subpixels SP disposed in the pixel layer 240 may be disposed in the control line areas CLB1, CLB2. For example, when the subpixel SP is configured with a circuit as shown in FIG. 9, the control line areas CLB1, CLB2 may include an initialization voltage line ViniL transmitting an initialization voltage configured to initialize the subpixel SP, or a mode control signal line PSL transmitting a mode control signal configured to control the operation mode of the subpixel SP.

In addition, control signal lines transmitting the control signals to the gate driving integrated circuit GDIC disposed in the gate circuit areas GDB1, GDB2, GDB3 may be further disposed in the control line areas CLB1, CLB2.

The gate circuit areas GDB1, GDB2, GDB3 and the control line areas CLB1, CLB2 may be disposed so as not to overlap the emission area EA formed by the subpixel SP of the pixel layer 240. In this case, the emission area EA of the subpixel SP may be located between the gate circuit areas GDB1, GDB2, GDB3 and the control line areas CLB1, CLB2.

Alternatively, when the display panel 110 is top emission, the gate circuit areas GDB1, GDB2, GDB3 and the control line areas CLB1, CLB2 below the pixel layer 240 may be disposed so as to overlap a portion of the emission area EA.

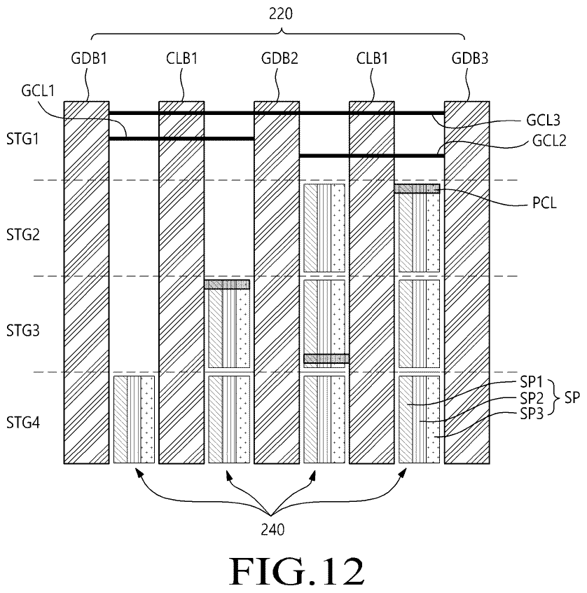

FIG. 12 is a plan view illustrating a base circuit layer and a pixel layer according to embodiments of the present disclosure.

Referring to FIG. 12, a base circuit layer 220 constituting the gate driving circuit 120 and a pixel layer 240 may be disposed in the display area DA of the display panel 110 according to aspects of the present disclosure.

The base circuit layer 220 disposed over the substrate 210 may include gate circuit areas GDB1, GDB2, GDB3 and control line areas CLB1, CLB2.

The gate driving integrated circuit GDIC may be disposed in the gate circuit area GDB1, GDB2, GDB3, and the control signal line configured to transmit a control signal may be disposed in the control line area CLB1, CLB2.

The pixel layer 240 may include a first subpixel SP1 emitting red color, a second subpixel SP2 emitting green color, and a third subpixel SP3 emitting blue color as a pixel.

The subpixels SP disposed in the pixel layer 240 may be located between the gate circuit area GDB1, GDB2, GDB3 and the control line area CLB1, CLB2. In this case, the gate circuit areas GDB1, GDB2, GDB3 and the control line areas CLB1, CLB2 may be disposed so as not to overlap the subpixels SP.

For another example, some of the gate circuit areas GDB1, GDB2, GDB3 or the control line areas CLB1, CLB2 may be disposed to overlap the subpixels SP.

A gate control signal lines transmitting the control signal to the gate circuit areas GDB1, GDB2, GDB3 or a pixel control signal line PCL transmitting the control signal to a plurality of subpixels SP may be disposed in the control line areas CLB1, CLB2.

For example, a pixel control signal line PCL, such as an initialization voltage line configured to initialize the subpixel SP or a mode control signal line configured to control the operation mode of the subpixel SP may be disposed in the control line area CLB1, CLB2. In this case, the pixel control signal line PCL may be electrically connected to the corresponding subpixel SP through a contact hole from the control line area CLB1, CLB2.

The display apparatus 100 of the present disclosure may include shielding layers on the upper and lower (or the top and bottom) of the base circuit layer 220 where the gate driving circuit 120 is disposed in the display area DA to reduce the parasitic capacitance formed in the base circuit layer 200.

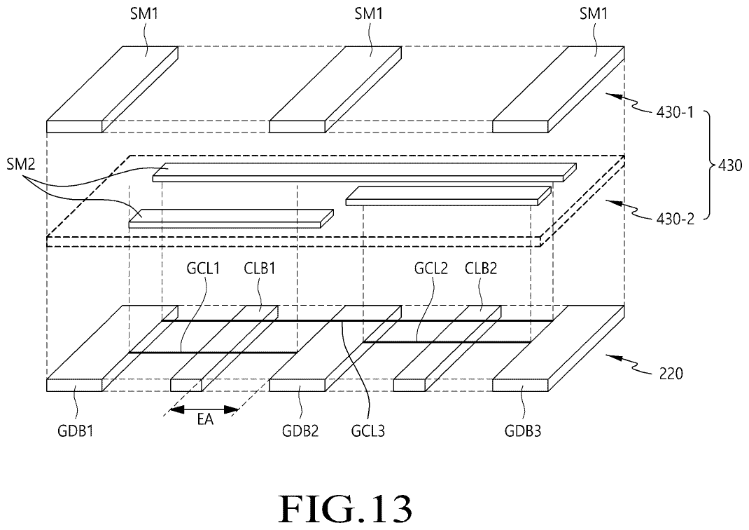

FIG. 13 is a perspective view illustrating a shielding structure according to embodiments of the present disclosure.

Referring to FIG. 13, a first shielding layer 430 may be disposed between the base circuit layer 220 including the gate driving circuit 120 in the display area DA and the pixel layer 240 including the subpixels SP in the display apparatus 100 according to aspects of the present disclosure.

The first shielding layer 430 may reduce parasitic capacitance formed between the base circuit layer 220 and the pixel layer 240.

The first shielding layer 430 may include a 1-1 shielding layer 430-1 and a 1-2 shielding layer 430-2.

The 1-1 shielding layer 430-1 may be disposed at a position corresponding to the plurality of gate circuit areas GDB1, GDB2, GDB3. The 1-1 shielding layer 430-1 may shield the gate circuit areas GDB1, GDB2, GDB3 of the base circuit layer 220. The 1-1 shielding layer 430-1 may be formed of a first shielding metal SM1 formed at a position corresponding to the gate circuit areas GDB1, GDB2, GDB3.

The 1-2 shielding layer 430-2 may be disposed at a position corresponding to at least one gate connection lines GCL1, GCL2, GCL3. The 1-2 shielding layer 430-2 may shield the gate connection lines GCL1, GCL2, GCL3 connecting the gate circuit areas GDB1, GDB2, GDB3. The 1-2 shielding layer 430-2 may be formed of a second shielding metal SM2 formed at a position corresponding to the gate connection lines GCL1, GCL2, GCL3 connecting the gate circuit areas GDB1, GDB2, GDB3.

The first shielding metal SM1 may be formed of a same material as the second shielding metal SM2, but aspects of the present disclosure are not limited thereto.

The 1-1 shielding layer 430-1 may be disposed on the same layer as the 1-2 shielding layer 430-2, or may be disposed on different layers.

The 1-1 shielding layer 430-1 may be electrically connected to the 1-2 shielding layer 430-2.

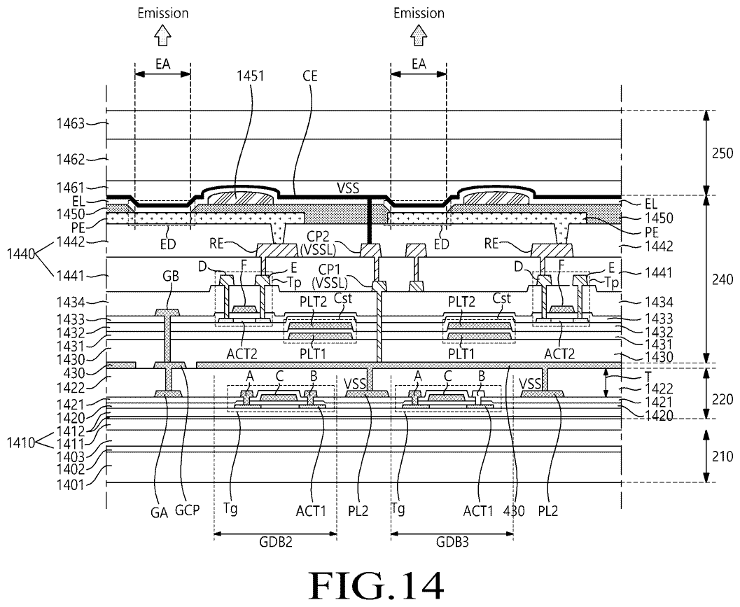

FIG. 14 is a cross-sectional view of a display area according to embodiments of the present disclosure.

Referring to FIG. 14, the display area DA of the display panel 110 according to aspects of the present disclosure may include a substrate 210, a base circuit layer 220, a pixel layer 240, an encapsulation layer 250 and a first shielding layer 430.

The substrate 210 may include a first substrate 1401, an intermediate layer 1402, and a second substrate 1403. The intermediate layer 1402 may be disposed between the first substrate 1401 and the second substrate 1403. For example, at least one of the first substrate 1401 and the second substrate 1403 may be a substrate including polyimide (PI).

The base circuit layer 220 may be disposed over the substrate 210.

The base circuit layer 220 may include a plurality of gate transistors Tg, and one or more insulating films 1410, 1420, 1421 for forming the plurality of gate transistors Tg.

The plurality of gate transistors Tg may comprise of the gate driving circuit 120. Each of the plurality of gate transistors Tg may include a first active layer ACT1, a first source electrode A, a first drain electrode B, and a first gate electrode C.

The one or more insulating films 1410, 1420, 1421 may form a plurality of gate transistors Tg. The one or more insulating films 1410, 1420, 1421 may include a first buffer layer 1410, a first gate insulating film 1420, and a first interlayer insulating film 1421.

The first buffer layer 1410 may be disposed on the second substrate 1403.

The first buffer layer 1410 may include a multi-buffer layer 1411 and an active buffer layer 1412. The multi-buffer layer 1411 may be disposed on the second substrate 1403. The active buffer layer 1412 may be disposed on the multi-buffer layer 1411.

The first active layer ACT1 may be disposed on the active buffer layer 1412.

The first gate insulating film 1420 may be disposed on the first active layer ACT1.

The first gate electrode C may be disposed on the first gate insulating film 1420, and may overlap with a portion of the first active layer ACT1. A portion of the first active layer ACT1 overlapping with the first gate electrode C may be a channel area.

The first interlayer insulating film 1421 may be disposed on the first gate electrode C.

The first source electrode A and the first drain electrode B may be disposed on the first interlayer insulating film 1421. The first source electrode A may be electrically connected to a first portion of the first active layer ACT1 through a first contact hole of the first interlayer insulating film 1421. The first drain electrode B may be electrically connected to a second portion of the first active layer ACT1 through a second contact hole of the first interlayer insulating film 1421. The area between the first portion and the second portion of the first active layer ACT1 may be a channel area.

The transistor included in the gate driving circuit 120 may be referred to as a gate transistor Tg. The transistors included in the gate driving circuit 120 may include a pull-up transistor Tu and a pull-down transistor Td included in a output buffer of the gate driving circuit 120, and other transistors, but aspects of the present disclosure are not limited thereto.

The base circuit layer 220 may include not only the gate driving circuit 120 but also plurality of pixel voltage lines PL1, PL2 supplying a plurality of pixel driving voltages to the pixel layer 240. The plurality of pixel voltage lines PL1, PL2 may include a first pixel voltage line PL1 supplying a high-potential pixel driving voltage to the pixel layer 240 and a second pixel voltage line PL2 supplying a low-potential pixel driving voltage to the pixel layer 240 to the pixel layer 240.

The base circuit layer 220 may include an organic layer 1422 disposed on a plurality of gate transistors Tg included in the gate driving circuit 120.

The organic layer 1422 may be disposed on a plurality of gate transistors Tg and a plurality of pixel voltage lines PL1, PL2 included in the gate driving circuit 120 to reduce a step in the base circuit layer 220.

In addition, the organic layer 1422 may reduce unnecessary parasitic capacitance between a metal disposed on the base circuit layer 220 and a metal disposed within the base circuit layer 220.

An upper surface of the organic layer 1422 may have a smaller step than a back surface of the organic layer 1422.

The organic layer 1422 may have a thickness T greater than a thickness of the first gate insulating film 1420 between the first gate electrode C and the first active layer ACT1 of each of the plurality of gate transistors Tg.

The first shielding layer 430 may be disposed on the organic layer 1422 of the base circuit layer 220. The pixel layer 240 may be disposed on the first shielding layer 430. For example, the first shielding layer 430 may be disposed between the base circuit layer 220 and the pixel layer 240. Accordingly, the parasitic capacitance between the base circuit layer 220 and the pixel layer 240 may be reduced.

The first shielding layer 430 may include a 1-1 shielding metal and a 1-2 shielding metal. The 1-1 shielding metal may cover the gate circuit areas GDB2, GDB3 of the base circuit layer 220. For example, the 1-1 shielding metal may overlap the gate circuit areas GDB2, GDB3 of the base circuit layer 220. The 1-2 shielding metal may cover the gate connection line GCL connecting the gate circuit areas GDB2, GDB3. For example, the 1-2 shielding metal may overlap the gate connection line GCL connecting the gate circuit areas GDB2, GDB3. The 1-1 shielding metal may be disposed on the same layer as the 1-2 shielding metal, but aspects of the present disclosure are not limited thereto.

The first shielding layer 430 may be electrically connected to a second pixel voltage line PL2 through a contact hole in the organic layer 1422. The second pixel voltage line PL2 may be a signal line supplying the low-potential pixel driving voltage.

The plurality of pixel voltage lines PL1, PL2 disposed in the base circuit layer 220 may include the same material as the first source electrode A and first drain electrode B of the gate transistor Tg, but aspects of the present disclosure are not limited thereto.

The pixel layer 240 may include a plurality of pixel transistors Tp, a plurality of storage capacitors Cst, and a plurality of light emitting element ED.

The pixel layer 240 may include a second buffer layer 1430, a second interlayer insulating film 1431, a third interlayer insulating film 1432, a second gate insulating film 1433, a fourth interlayer insulating film 1434, a planarization film 1440, a bank 1450, and a spacer 1451. Here, the planarization film 1440 may include a first planarization film 1441 and a second planarization film 1442. The planarization film 1440 may be a pixel planarization film, but aspects of the present disclosure are not limited thereto.

Each of the plurality of pixel transistors Tp may include a second active layer ACT2, a second source electrode D, a second drain electrode E, and a second gate electrode F.

Each of the plurality of storage capacitors Cst may include a first capacitor electrode PLT1 and a second capacitor electrode PLT2.

Each of the plurality of light emitting elements ED may include a pixel electrode PE, an element intermediate layer EL, and a common electrode CE.

The second buffer layer 1430 may be disposed on the first shielding layer 430.

The first capacitor electrode PLT1 may be disposed on the second buffer layer 1430. The second interlayer insulating film 1431 may be disposed on the first capacitor electrode PLT1. The second capacitor electrode PLT2 may be disposed on the second interlayer insulating film 1431.

The first capacitor electrode PLT1 may overlap with the second capacitor electrode PLT2 to form a storage capacitor Cst.

The third interlayer insulating film 1432 may be disposed on the second capacitor electrode PLT2.

The second active layer ACT2 may be disposed on the third interlayer insulating film 1432.

The second gate insulating film 1433 may be disposed on the second active layer ACT2, and the second gate electrode F may be disposed on the second gate insulating film 1433. The second gate electrode F may overlap a portion of the second active layer ACT2. An area of the second active layer ACT2 overlapping with the second gate electrode F may be a channel area.

The fourth interlayer insulating film 1434 may be disposed on the second gate electrode F. The second source electrode E and the second drain electrode D may be disposed on the fourth interlayer insulating film 1434.

The second source electrode E may be electrically connected to a first portion of the second active layer ACT2 through a first contact hole of the fourth interlayer insulating film 1434, and the second drain electrode D may be electrically connected to a second portion of the second active layer ACT2 through a second contact hole of the fourth interlayer insulating film 1434. The area between the first and second portions of the second active layer ACT2 may be a channel area.

The planarization film 1440 may be disposed on the second source electrode E and the second drain electrode D. The pixel electrode PE may be disposed on the planarization film 1440, and may be electrically connected to the second source electrode E or the second drain electrode D through a contact hole in the planarization film 1440.

In the case that the planarization film 1440 includes the first planarization film 1441 and the second planarization film 1442, the first planarization film 1441 may be disposed on the second source electrode E and the second drain electrode D. A relay electrode RE may be disposed on the first planarization film 1441 and electrically connected to the second source electrode E or the second drain electrode D through a contact hole in the first planarization film 1441. The second planarization film 1442 may be disposed on the relay electrode RE. The pixel electrode PE may be disposed on the second planarization film 1442, and may be electrically connected to the relay electrode RE through a contact hole in the second planarization film 1442.

The bank 1450 may be disposed on the pixel electrode PE, and may have an opening corresponding to an emission area EA.

The element intermediate layer EL may be disposed on the bank 1450, and may contact the pixel electrode PE at the opening of the bank 1450. The spacer 1451 may be disposed on the bank 1450 at some portion (e.g., a portion overlapping the pixel electrode PE or a boundary portion of the emission area EA). The bank 1450 may be formed of a material containing black pigment, or an organic material such as benzocyclobutene resin, polyimide resin, acrylic resin, or photosensitive polymer, but aspects of the present disclosure are not limited thereto. When the bank 1450 is formed of a material containing black pigment or black dye, it may be a black bank. When the bank 1450 is formed of a material containing black pigment or black dye, light from the outside may be blocked and the luminance of the display apparatus may be further improved.

The common electrode CE may be disposed on the element intermediate layer EL.

An area where the pixel electrode PE, the element intermediate layer EL, and the common electrode CE overlap without another insulating film may form the emission area EA.

When the light emitting element ED is an organic light emitting element, the element intermediate layer EL may include an emission layer EML disposed only in and near the emission area EA, a first common layer between the anode electrode and the emission layer, and a second common layer between the emission layer and the cathode electrode. Here, the anode electrode may be a pixel electrode PE or a common electrode CE, and the cathode electrode may be a common electrode CE or a pixel electrode PE.

The first common layer may include a hole injecting layer HIL and a hole transporting layer HTL, but aspects of the present disclosure are not limited thereto. The second common layer may include an electron transporting layer ETL and an electron injecting layer EIL, but aspects of the present disclosure are not limited thereto. The hole injecting layer may inject holes from the anode electrode to the hole transporting layer, the hole transporting layer may transport holes to the emission layer. The electron injecting layer may inject electrons from the cathode electrode to the electron transporting layer, and the electron transporting layer may transport electrons to the emission layer. The emission layer of the element intermediate layer EL may be disposed in each subpixel SP, and the first and second common layers of the element intermediate layer EL may be commonly disposed in a plurality of subpixels SP.

The encapsulation layer 250 may be disposed on the pixel layer 240.

The encapsulation layer 250 may include one or more encapsulation layers. The encapsulation layer 250 may include a first encapsulation layer 1461, a second encapsulation layer 1462, and a third encapsulation layer 1463, but aspects of the present disclosure are not limited thereto. For example, the first encapsulation layer 1461 and the third encapsulation layer 1463 may be inorganic layers, and the second encapsulation layer 1462 may be an organic layer, but aspects of the present disclosure are not limited thereto.

A first metal GA in the base circuit layer 220 may be electrically connected to a second metal GB in the pixel layer 240 through the opening of the first shielding layer 430.

Further, the first metal GA in the base circuit layer 220 may be electrically connected to the second metal GB in the pixel layer 240 through a connection metal GCP separated from the first shielding layer 430. Here, the connection metal GCP may include a same material as the first shielding layer 430, and may be disposed in the same layer as the first shielding layer 430, but aspects of the present disclosure are not limited thereto.

The second metal GB in the pixel layer 240 may be disposed on the second gate insulating film 1433. The second metal GB may include a same material as the second gate electrode F, and may be disposed in the same layer, but aspects of the present disclosure are not limited thereto.

The first metal GA in the base circuit layer 220 may be disposed on the first interlayer insulating film 1421.

The second metal GB in the pixel layer 240 may be electrically connected to the first metal GA in the base circuit layer 220 through the contact holes in the second buffer layer 1430, the second interlayer insulating film 1431, the third interlayer insulating film 1432, the second gate insulating film 1433, the first shielding layer 430, and the organic layer 1422.

The base circuit layer 220 may include a gate transistor Tg including a first active layer ACT1. The pixel layer 240 may include a pixel transistor Tp including a second active layer ACT2.

The first active layer ACT1 may include different semiconductor materials from the second active layer ACT2. For example, the first active layer ACT1 may include a silicon-based semiconductor material, but aspects of the present disclosure are not limited thereto. The second active layer ACT2 may include an oxide-based semiconductor material, but aspects of the present disclosure are not limited thereto. For example, at least one of the first active layer ACT1 and the second active layer ACT2 may include an oxide semiconductor layer or a low-temperature polysilicon semiconductor layer, but aspects of the present disclosure are not limited thereto.

For example, the silicon-based semiconductor material may include amorphous silicon (a-Si) or a low-temperature polycrystalline silicon (LTPS).

For example, oxide-based semiconductor materials may include indium gallium zinc oxide (IGZO), indium gallium zinc tin oxide (IGZTO), zinc oxide (ZnO), cadmium oxide (CdO), indium oxide (InO), zinc tin oxide (ZTO), and zinc indium tin oxide (ZITO), and may also include a low-temperature polycrystalline oxide (LTPO), but aspects of the present disclosure are not limited thereto.

The first active layer ACT1 and/or the second active layer ACT2 may be a single layer or a multi-layer. For example, when the first active layer ACT1 and/or the second active layer ACT2 are the multi-layer, the multilayers may be composed of the same semiconductor material or may be composed of two or more different semiconductor materials, but aspects of the present disclosure are not limited thereto.

The encapsulation layer 250 and the common electrode CE may overlap with the gate driving circuit 120. The common electrode CE may be an electrode capable of transmitting light. The pixel electrode PE may be a reflective electrode. The pixel electrode PE may overlap with at least a portion of the gate driving circuit 120.

The emission area EA, where the pixel electrode PE overlaps with the common electrode CE to form an opening, may be disposed so as not to overlap with the gate circuit areas GDB2, GDB3. Alternatively, the emission area EA, where the pixel electrode PE overlaps with the common electrode CE to form an opening, may overlap a portion of the gate circuit areas GDB2, GDB3.

Here, it illustrates a case where the second gate circuit area GDB2 does not overlap with the emission area EA and the third gate circuit area GDB3 partially overlaps with the emission area EA, but aspects of the present disclosure are not limited thereto.

When the display panel 110 has a top emission structure, the gate circuit areas GDB2, GDB3 may overlap with the emission area EA.

A low-potential pixel driving voltage may be supplied to the first shielding layer 340 and the second shielding layer 450 included in the display panel 110 according to aspects of the present disclosure.

The first shielding layer 430 may be electrically connected to the common electrode CE to which the low-potential pixel driving voltage is supplied.

The common electrode CE may be electrically connected to the first shielding layer 430 through a first connection pattern CP1 and a second connection pattern CP2.

The first connection pattern CP1 may be disposed on the fourth interlayer insulating film 1434. The first connection pattern CP1 may be composed of a metal. The first connection pattern CP1 may be connected to the first shielding layer 430 through a contact hole in the second buffer layer 1430, the second interlayer insulating film 1431, the third interlayer insulating film 1432, the second gate insulating film 1433, and the fourth interlayer insulating film 1434.

The second connection pattern CP2 may be disposed on the first planarization film 1441. The second connection pattern CP2 may be composed of a metal. The second connection pattern CP2 may be connected to the first connection pattern CP1 through a contact hole in the first planarization film 1441.

The first connection pattern CP1 and the second connection pattern CP2 may be electrically connected to the low-potential pixel voltage line VSSL disposed in the pixel layer 240. At least one or more of the first connection pattern CP1 and the second connection pattern CP2 may be a low-potential pixel voltage line VSSL disposed in the pixel layer 240.

The common electrode CE in the pixel layer 240 may be connected to the second pixel voltage line PL2 in the base circuit layer 220 through the first connection pattern CP1, the second connection patterns CP2 and the first shielding layer 430.

The first shielding layer 430 in the display panel 110 of the present disclosure may have a structure that a 1-1 shielding layer 430-1 configured to shield the gate circuit areas GDB1, GDB2, GDB3 of the base circuit layer 220 is disposed on a layer different from the 1-2 shielding layer 430-2 configured to shield the gate connection lines GCL1, GCL2, GCL3 connecting the gate circuit areas GDB1, GDB2, GDB3, but aspects of the present disclosure are not limited thereto.

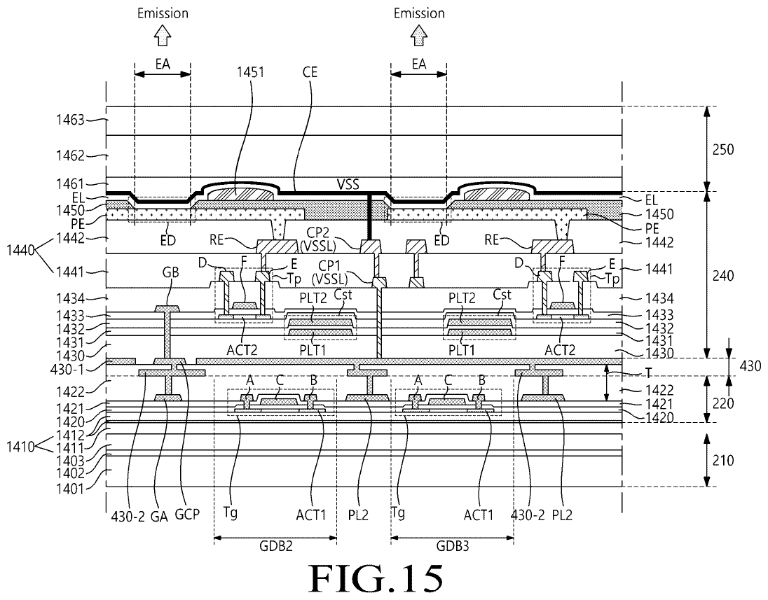

FIG. 15 is a cross-sectional view illustrating a display area according to embodiments of the present disclosure.

FIG. 15 illustrates a display area including a first shielding double-layer and a second shielding single-layer. Here, the description will focus on parts that are different from FIG. 14.

Referring to FIG. 15, the display area DA of the display panel 110 according to aspects of the present disclosure may include a substrate 210, a base circuit layer 220, a pixel layer 240, an encapsulation layer 250, a 1-1 shielding layer 430-1, and a 1-2 shielding layer 430-2.

The base circuit layer 220 may include an organic layer 1422 disposed over a plurality of gate transistors Tg included in the gate driving circuit 120.

The 1-2 shielding layer 430-2 may be disposed on the organic layer 1422 of the base circuit layer 220. The pixel layer 240 may be disposed on the first shielding layer 430. The 1-2 shielding layer 430-2 may be formed to cover the gate connection line GCL connecting the gate circuit areas GDB2, GDB3. For example, the 1-2 shielding layer 430-2 may overlap with the gate connection line GCL connecting the gate circuit areas GDB2, GDB3.

A planarization film 1423 may be disposed on the 1-2 shielding layer 430-2. The planarization film 1423 may be a gate planarization film, but aspects of the present disclosure are not limited thereto.

The 1-1 shielding layer 430-1 may be disposed on the planarization film 1423. The 1-1 shielding layer 430-1 may be formed to cover the gate circuit areas GDB2, GDB3 of the base circuit layer 220. For example, the 1-1 shielding layer 430-1 may overlap with the gate circuit areas GDB2, GDB3 of the base circuit layer 220.

The 1-1 shielding metal may be formed in different layers from the 1-2 shielding metal, but aspects of the present disclosure are not limited thereto.

The display apparatus 100 of the present disclosure may reduce the parasitic capacitance between the base circuit layer 220 and the pixel layer 240 by a 1-1 shielding layer 430-1 and a 1-2 shielding layer 430-2 located between the base circuit layer 220 and the pixel layer 240.

The display apparatus 100 of the present disclosure may provide not only an image display function but also a touch sensing function.

In this case, a touch electrode structure for touch sensing operation may include a plurality of X-touch electrode lines and a plurality of Y-touch electrode lines. The plurality of X-touch electrode lines and the plurality of Y-touch electrode lines may be disposed over the encapsulation layer 250. For example, a touch part may be formed on the encapsulation layer 250.

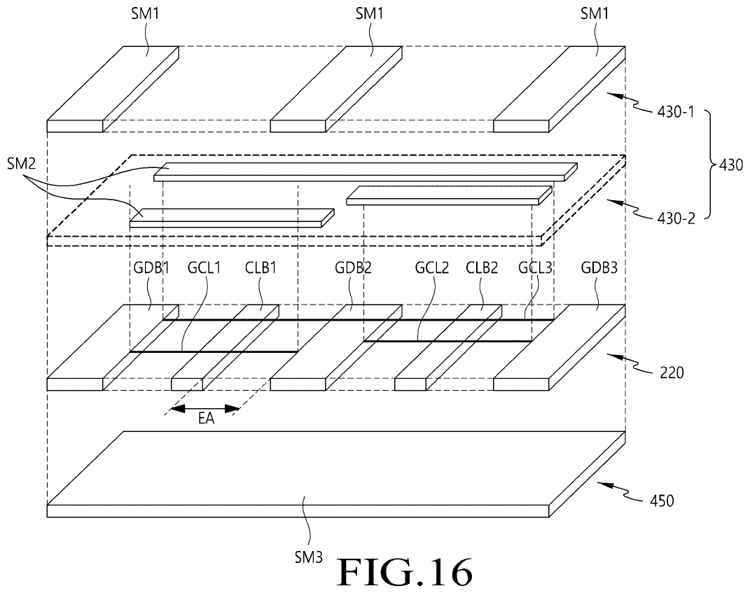

FIG. 16 is a perspective view illustrating an example of a shielding layer according to embodiments of the present disclosure.

Referring to FIG. 16, the display apparatus 100 according to aspects of the present disclosure may include a first shielding layer 430 disposed between a base circuit layer 220 on which the gate driving circuit 120 is disposed in the display area DA and a pixel layer 240 in which a plurality of subpixels SP are disposed.

The first shielding layer 430 may reduce parasitic capacitance formed between the base circuit layer 220 and the pixel layer 240.

The first shielding layer 430 may include a 1-1 shielding layer 430-1 and a 1-2 shielding layer 430-2.

The 1-1 shielding layer 430-1 may shield the gate circuit areas GDB1, GDB2, GDB3 of the base circuit layer 220. The 1-1 shielding layer 430-1 may be formed of a first shielding metal SM1 formed at a position corresponding to the gate circuit areas GDB1, GDB2, GDB3.

The 1-2 shielding layer 430-2 may shield the gate connection lines GCL1, GCL2, GCL3 connecting the gate circuit areas GDB1, GDB2, GDB3. The 1-2 shielding layer 430-2 may be formed of a second shielding metal SM2 formed at a position corresponding to the gate connection lines GCL1, GCL2, GCL3 connecting the gate circuit areas GDB1, GDB2, GDB3.

The first shielding metal SM1 may be formed of the same material as the second shielding metal SM2, but aspects of the present disclosure are not limited thereto.

The 1-1 shielding layer 430-1 may be disposed on the same layer as the 1-2 shielding layer 430-2, or may be disposed on different layers.

The 1-1 shielding layer 430-1 may be electrically connected to the 1-2 shielding layer 430-2.

Additionally, the second shielding layer 450 may be disposed between the base circuit layer 220 and the substrate 210. The second shielding layer 450 may reduce parasitic capacitance between internal nodes or signal lines of the gate driving integrated circuit GDIC disposed in the base circuit layer 220.

The second shielding layer 450 may be formed of the third shielding metal SM3. The third shielding metal SM3 may be formed to cover all of the gate circuit areas GDB1, GDB2, GDB3, the gate connection lines GCL1, GCL2, GCL3, and the emission area EA. For example, the second shielding layer 450 may overlap with the gate circuit areas GDB1, GDB2, GDB3, the gate connection lines GCL1, GCL2, GCL3, and the emission area EA. For example, the second shielding layer 450 may overlap with at least one or more of the gate circuit areas GDB1, GDB2, GDB3, gate connection lines GCL1, GCL2, GCL3, and the emission area EA.

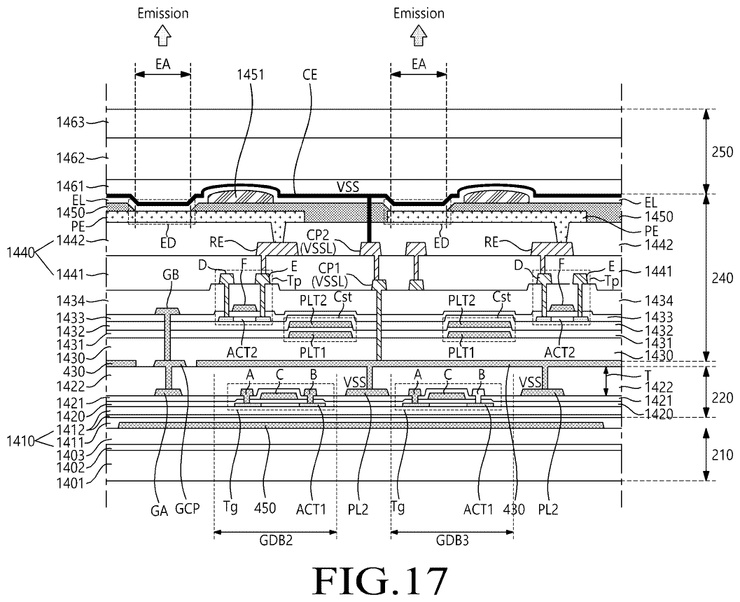

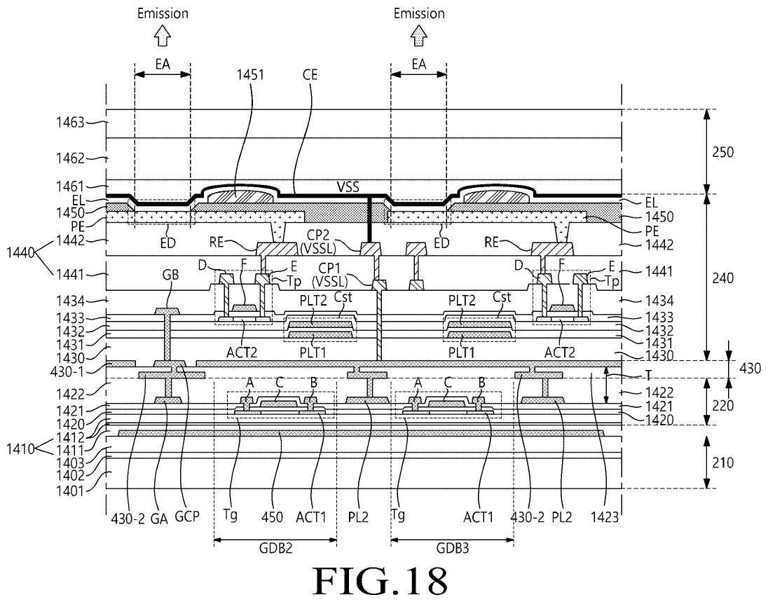

FIGS. 17 and 18 are cross-sectional views illustrating a display area according to embodiments of the present disclosure.

FIGS. 17 and 18 illustrate a structure in which a second shielding layer 450 is further disposed between the base circuit layer 220 and the substrate 210 in FIGS. 14 and 15.

Referring to FIG. 17, the display area DA of the display panel 110 according to aspects of the present disclosure may include a substrate 210, a base circuit layer 220, a pixel layer 240, an encapsulation layer 250, a first shielding layer 430, and a second shielding layer 450.

The second shielding layer 450 may reduce parasitic capacitance between internal nodes or signal lines of the gate driving circuit 120 disposed in the base circuit layer 220. The second shielding layer 450 may be formed to cover all of the gate circuit areas GDB1, GDB2, GDB3, the gate connection lines GCL1, GCL2, GCL3, and the emission area EA. For example, the second shielding layer 450 may overlap with the gate circuit areas GDB1, GDB2, GDB3, the gate connection lines GCL1, GCL2, GCL3 and the emission area EA. For example, the second shielding layer 450 may overlap with at least one or more of the gate circuit areas GDB1, GDB2, GDB3, the gate connection lines GCL1, GCL2, GCL3, and the emission area EA.

The first buffer layer 1410 may be disposed on the second shielding layer 450.

The first buffer layer 1410 may include a multi-buffer layer 1411 and an active buffer layer 1412. The multi-buffer layer 1411 may be disposed on the second shielding layer 450. The active buffer layer 1412 may be disposed on the multi-buffer layer 1411.

A low-potential pixel driving voltage may be supplied to the first shielding layer 430 and the second shielding layer 450 included in the display panel 110 according to aspects of the present disclosure.

Referring to FIG. 18, the display area DA of the display panel 110 according to aspects of the present disclosure may include a substrate 210, a base circuit layer 220, a pixel layer 240, an encapsulation layer 250, a first shielding layer 430, and a second shielding layer 450.

The first shielding layer 430 may include a 1-1 shielding layer 430-1 for shielding the gate circuit areas GDB1, GDB2, GDB3 in the base circuit layer 220 and a 1-2 shielding layer 430-2 for shielding the gate connection lines GCL1, GCL2, GCL3 connecting the gate circuit areas GDB1, GDB2, GDB3. The 1-1 shielding layer 430-1 may be disposed in different layer from the 1-2 shielding layer 430-2.

A second shielding layer 450 may be disposed between the base circuit layer 220 and the substrate 210.

The second shielding layer 450 may reduce parasitic capacitance between internal nodes or signal lines of the gate driving circuit 120 constituting the base circuit layer 220. The second shielding layer 450 may be formed to cover all of the gate circuit areas GDB1, GDB2, GDB3, gate connection lines GCL1, GCL2, GCL3, and the emission area EA.

Therefore, the display apparatus 100 of the present disclosure may dispose shielding layers on the upper and lower (or the top and bottom) of the base circuit layer 220 including the gate driving circuit 120 in the display area DA to reduce parasitic capacitance formed in the base circuit layer 220.

A display apparatus and a display panel according to embodiments of the present disclosure are described below.

A display apparatus according to embodiments of the present disclosure may comprise a substrate, a base circuit layer on the substrate, the base circuit layer including a gate driving circuit, a pixel layer on the base circuit layer, the pixel layer including a plurality of subpixels, a first shielding layer between the base circuit layer and the pixel layer, and a second shielding layer between the substrate and the base circuit layer.

According to embodiments of the present disclosure, the base circuit layer may comprise a plurality of gate circuit areas, and a plurality of control line areas disposed between the plurality of gate circuit areas.

According to embodiments of the present disclosure, a gate driving integrated circuit constituting the gate driving circuit may be divided and disposed in the plurality of gate circuit areas.

According to embodiments of the present disclosure, the gate driving integrated circuit may be provided in a display area of the substrate.

According to embodiments of the present disclosure, the plurality of gate circuit areas may comprise a first gate circuit area including at least one transistor connected to a first node of the gate driving integrated circuit, a second gate circuit area including at least one transistor connected to a second node of the gate driving integrated circuit, and a third gate circuit area including at least one transistor connected to a third node of the gate driving integrated circuit.

According to embodiments of the present disclosure, the first node may control a gate high voltage of the gate driving integrated circuit. The second node may control a gate low voltage of the gate driving integrated circuit. The third node may receive a gate start signal from the gate driving integrated circuit.

According to embodiments of the present disclosure, the plurality of gate circuit areas may be electrically connected through at least one gate connection line.

According to embodiments of the present disclosure, the first shielding layer may include a 1-1 shielding layer at a position corresponding to the plurality of gate circuit areas, and a 1-2 shielding layer at a position corresponding to at least one gate connection line. The at least one gate connection line may be electrically connected to the plurality of gate circuit areas.

According to embodiments of the present disclosure, the 1-1 shielding layer may be on a different layer from the 1-2 shielding layer.

According to embodiments of the present disclosure, the 1-1 shielding layer may be electrically connected to the 1-2 shielding layer.

According to embodiments of the present disclosure, the first shielding layer may be electrically connected to a source electrode or a drain electrode of a driving transistor included in the pixel layer.

According to embodiments of the present disclosure, the first shielding layer may be electrically connected to a low-potential pixel voltage line in the pixel layer.

According to embodiments of the present disclosure, the display apparatus may further comprise an initialization voltage line supplying an initialization voltage to the plurality of subpixels disposed in the pixel layer, or a mode control signal line supplying a mode control signal to the plurality of subpixels may be disposed in the plurality of control line areas.

According to embodiments of the present disclosure, the pixel layer includes subpixels including a first subpixel with a first emission angle and a second subpixel with a second emission angle. The mode control signal line may include a first mode control signal line connected to the first subpixel and a second mode control signal line connected to the second subpixel.

According to embodiments of the present disclosure, the plurality of gate circuit areas and the plurality of control line areas may be non-overlapping with emission areas of the pixel layer.

According to embodiments of the present disclosure, the second shielding layer may correspond to the base circuit layer.

According to embodiments of the present disclosure, the second shielding layer may be electrically connected to a low-potential gate voltage line of the base circuit layer.

A display panel according to embodiments of the present disclosure may comprise a substrate, a base circuit layer on the substrate, the base circuit layer including a gate driving circuit, a pixel layer on the base circuit layer, the pixel layer including a plurality of subpixels, a first shielding layer between the base circuit layer and the pixel layer, and a second shielding layer between the substrate and the base circuit layer.

A display apparatus according to embodiments of the present disclosure may comprise a substrate, a base circuit layer on the substrate, the base circuit layer including a gate driving circuit, a pixel layer on the base circuit layer, the pixel layer including a plurality of subpixels, and a shielding layer between the base circuit layer and the pixel layer.

According to embodiments of the present disclosure, the base circuit layer may comprise a plurality of gate circuit areas, and a plurality of control line areas between the plurality of gate circuit areas.

According to embodiments of the present disclosure, the second shielding layer may correspond to an entire portion of the base circuit layer.

According to embodiments of the present disclosure, a gate driving integrated circuit constituting the gate driving circuit may be divided and disposed in the plurality of gate circuit areas.

According to embodiments of the present disclosure, the gate driving circuit may be provided in a display area of the substrate.

According to embodiments of the present disclosure, the plurality of gate circuit areas may comprise a first gate circuit area including at least one transistor connected to a first node of the gate driving integrated circuit, a second gate circuit area including at least one transistor connected to a second node of the gate driving integrated circuit, and a third gate circuit area including at least one transistor connected to a third node of the gate driving integrated circuit.

According to embodiments of the present disclosure, the first node may control a gate high voltage of the gate driving integrated circuit. The second node may control a gate low voltage of the gate driving integrated circuit. The third node may receive a gate start signal from the gate driving integrated circuit.

According to embodiments of the present disclosure, the plurality of gate circuit areas may be electrically connected through at least one gate connection line.

According to embodiments of the present disclosure, the shielding layer may include a first shielding layer at a position corresponding to the plurality of gate circuit areas, and a second shielding layer at a position corresponding to the at least one gate connection line.

According to embodiments of the present disclosure, the first shielding layer may be on a different layer from the second shielding layer.

According to embodiments of the present disclosure, the first shielding layer may be electrically connected to the second shielding layer.

According to embodiments of the present disclosure, the shielding layer may be electrically connected to a source electrode or a drain electrode of a driving transistor in the pixel layer.

According to embodiments of the present disclosure, the shielding layer may be electrically connected to a low-potential pixel voltage line in the pixel layer.

According to embodiments of the present disclosure, the display apparatus may further comprise an initialization voltage line supplying an initialization voltage to the plurality of subpixels in the pixel layer, or a mode control signal line supplying a mode control signal to the plurality of subpixels may be in the plurality of control line areas.

According to embodiments of the present disclosure, the pixel layer may include subpixels including a first subpixel with a first emission angle and a second subpixel with a second emission angle. The mode control signal may include a first mode control signal controlling the first subpixel and a second mode control signal controlling the second subpixel.

According to embodiments of the present disclosure, the plurality of gate circuit areas and the plurality of control line areas may be non-overlapping with emission areas of the pixel layer.

The display apparatus according to embodiments of the present disclosure may further comprise a transistor in a display area of the substrate, a light emitting element over the transistor, and an encapsulation layer over the light emitting element.

According to embodiments of the present disclosure, an active layer of the transistor may include an oxide semiconductor layer or a low-temperature polysilicon semiconductor layer.

The display apparatus according to embodiments of the present disclosure may further comprise a touch part on the encapsulation layer.

According to embodiments of the present disclosure, the light emitting element may include a first emission part and a second emission part between a first electrode and a second electrode. Each of the first emission part and the second emission part may include an emission layer that emits a same color.

According to embodiments of the present disclosure, the light emitting element may further include a charge generation layer between the first emission part and the second emission part to supply positive and negative charges to the first emission part and the second emission part, respectively.

According to embodiments of the present disclosure, the charge generation layer may be formed with a step.

According to embodiments of the present disclosure, the light emitting element may include a first subpixel area, a second subpixel area, and a third subpixel area. The emission layer in the first emission part may include a 1-1 emission layer corresponding to the first subpixel area, a 1-2 emission layer corresponding to the second subpixel area and a 1-3 emission layer corresponding to the third subpixel area. The thickness of the 1-1 emission layer, the 1-1 emission layer and the 1-1 emission layer may be different from each other.

It will be apparent to those skilled in the art that various modifications and variations may be made in the present disclosure without departing from the scope of the disclosures. Thus, it is intended that the present disclosure covers the modifications and variations of this disclosure that come within the scope of the appended claims and their equivalents.

What is claimed:

1. A display apparatus, comprising:
a substrate;
a base circuit layer on the substrate, the base circuit layer including a gate driving circuit;
a pixel layer on the base circuit layer, the pixel layer including a plurality of subpixels;
a first shielding layer between the base circuit layer and the pixel layer; and
a second shielding layer between the substrate and the base circuit layer.

2. The display apparatus of claim 1, wherein the base circuit layer comprises:
a plurality of gate circuit areas; and
a plurality of control line areas between the plurality of gate circuit areas.

3. The display apparatus of claim 2, wherein a gate driving integrated circuit constituting the gate driving circuit is divided and disposed in the plurality of gate circuit areas.

4. The display apparatus of claim 3, wherein the plurality of gate circuit areas comprise:
a first gate circuit area including at least one transistor connected to a first node of the gate driving integrated circuit;
a second gate circuit area including at least one transistor connected to a second node of the gate driving integrated circuit; and
a third gate circuit area including at least one transistor connected to a third node of the gate driving integrated circuit.

5. The display apparatus of claim 4, wherein the first node controls a gate high voltage of the gate driving integrated circuit, the second node controls a gate low voltage of the gate driving integrated circuit, and the third node receives a gate start signal from the gate driving integrated circuit.

6. The display apparatus of claim 3, wherein the plurality of gate circuit areas are electrically connected by at least one gate connection line.

7. The display apparatus of claim 6, wherein the first shielding layer includes:
a first shielding layer at a position corresponding to the plurality of gate circuit areas; and
a second shielding layer at a position corresponding to the at least one gate connection line.

8. The display apparatus of claim 7, wherein the first shielding layer is on a different layer from the second shielding layer.

9. The display apparatus of claim 1, wherein the first shielding layer is electrically connected to a source electrode or a drain electrode of a driving transistor included in the pixel layer.

10. The display apparatus of claim 1, wherein the first shielding layer is electrically connected to a low-potential pixel voltage line in the pixel layer.

11. The display apparatus of claim 2, further comprising:
an initialization voltage line supplying an initialization voltage to the plurality of subpixels disposed at the pixel layer, or a mode control signal line supplying a mode control signal to the plurality of subpixels is disposed at the plurality of control line areas.

12. The display apparatus of claim 11, wherein the pixel layer includes subpixels including a first subpixel with a first emission angle and a second subpixel with a second emission angle, and
wherein the mode control signal line includes a first mode control signal line connected to the first subpixel and a second mode control signal line connected to the second subpixel.

13. The display apparatus of claim 2, wherein the plurality of gate circuit areas and the plurality of control line areas are non-overlapping with emission areas of the pixel layer.

14. The display apparatus of claim 1, wherein the second shielding layer corresponds to the base circuit layer.

15. The display apparatus of claim 1, wherein the second shielding layer is electrically connected to a low-potential gate voltage line of the base circuit layer.

16. A display panel, comprising:
a substrate;
a base circuit layer on the substrate, the base circuit layer including a gate driving circuit;
a pixel layer on the base circuit layer, the pixel layer including a plurality of subpixels;
a first shielding layer between the base circuit layer and the pixel layer; and
a second shielding layer between the substrate and the base circuit layer.

17. The display panel of claim 16, wherein the base circuit layer comprises:
a plurality of gate circuit areas; and
a plurality of control line areas between the plurality of gate circuit areas.

18. The display panel of claim 17, wherein the first shielding layer includes:
a first shielding layer at a position corresponding to the plurality of gate circuit areas; and
a second shielding layer at a position corresponding to at least one gate connection line.

19. The display panel of claim 16, wherein the second shielding layer corresponds to an entire portion of the base circuit layer.

20. A display apparatus, comprising:
a substrate;
a base circuit layer on the substrate, the base circuit layer including a gate driving circuit;
a pixel layer on the base circuit layer, the pixel layer including a plurality of subpixels; and
a shielding layer between the base circuit layer and the pixel layer.

21. The display apparatus of claim 20, wherein the base circuit layer comprises:
a plurality of gate circuit areas; and
a plurality of control line areas between the plurality of gate circuit areas.

22. The display apparatus of claim 21, wherein a gate driving integrated circuit constituting the gate driving circuit is divided and disposed in the plurality of gate circuit areas.

23. The display apparatus of claim 22, wherein the plurality of gate circuit areas comprise:
a first gate circuit area including at least one transistor connected to a first node of the gate driving integrated circuit;
a second gate circuit area including at least one transistor connected to a second node of the gate driving integrated circuit; and
a third gate circuit area including at least one transistor connected to a third node of the gate driving integrated circuit.

24. The display apparatus of claim 23, wherein the first node controls a gate high voltage of the gate driving integrated circuit, the second node controls a gate low voltage of the gate driving integrated circuit, and the third node receives a gate start signal from the gate driving integrated circuit.

25. The display apparatus of claim 21, wherein the plurality of gate circuit areas are electrically connected through at least one gate connection line.

26. The display apparatus of claim 25, wherein the shielding layer includes:
a first shielding layer at a position corresponding to the plurality of gate circuit areas; and
a second shielding layer at a position corresponding to the at least one gate connection line.

27. The display apparatus of claim 26, wherein the first shielding layer is on a different layer from the second shielding layer.

28. The display apparatus of claim 20, wherein the shielding layer is electrically connected to a source electrode or a drain electrode of a driving transistor in the pixel layer.

29. The display apparatus of claim 20, wherein the shielding layer is electrically connected to a low-potential pixel voltage line in the pixel layer.

30. The display apparatus of claim 21, further comprising:
an initialization voltage line supplying an initialization voltage to the plurality of subpixels in the pixel layer, or a mode control signal line supplying a mode control signal to the plurality of subpixels is in the plurality of control line areas.

31. The display apparatus of claim 30, wherein the pixel layer includes subpixels comprising a first subpixel with a first emission angle and a second subpixel with a second emission angle, and
wherein the mode control signal line includes a first mode control signal line connected to the first subpixel and a second mode control signal line connected to the second subpixel.

32. The display apparatus of claim 21, wherein the plurality of gate circuit areas and the plurality of control line areas are non-overlapping with emission areas of the pixel layer.

33. The display apparatus of claim 20, further comprising:
a transistor in a display area of the substrate;
a light emitting element over the transistor; and
an encapsulation layer over the light emitting element.

34. The display apparatus of claim 33, wherein an active layer of the transistor includes an oxide semiconductor layer or a low-temperature polysilicon semiconductor layer.

35. The display apparatus of claim 33 further comprising:
a touch part on the encapsulation layer.

36. The display apparatus of claim 33, wherein the light emitting element includes a first emission part and a second emission part between a first electrode and a second electrode, and
wherein each of the first emission part and the second emission part includes an emission layer that emits a same color.
